(19) United States
(12) Patent Application Publication
(10) Pub. No.: US 2025/0199135 A1
(43) Pub. Date: Jun. 19, 2025

(54) LIGHT EMITTING DEVICE AND DISTANCE MEASUREMENT APPARATUS

(71) Applicant: FUJIFILM Business Innovation Corp., Tokyo (JP)

(72) Inventors: Kei TAKEYAMA, Kanagawa (JP); Daisuke IGUCHI, Kanagawa (JP); Tomoaki SAKITA, Kanagawa (JP); Yoshihiro YAMAMOTO, Kanagawa (JP); Junichiro HAYAKAWA, Kanagawa (JP)

(73) Assignee: FUJIFILM Business Innovation Corp., Tokyo (JP)

(21) Appl. No.: 18/673,347

(22) Filed: May 24, 2024

(30) Foreign Application Priority Data
Dec. 13, 2023 (JP) 2023-210099

(51) Int. Cl. G01S 7/484; G01S 7/481; G01S 17/10

(52) U.S. Cl. CPC G01S 7/484; G01S 7/4815; G01S 17/10

(57) ABSTRACT

A light emitting device includes a light emitting unit that has a first light source irradiating a first irradiation region with light and a second light source irradiating a second irradiation region with light in a turned-on state and that arranges the first irradiation region and the second irradiation region to be parallel to each other or superimposed on each other at a reference distance and irradiates the first irradiation region and the second irradiation region with light, and a drive unit that drives the light emitting unit such that one of the first light source and the second light source is in a turned-on state and the other is in a turned-off state in a case where the light emitting unit irradiates a target object at a first distance different from the reference distance with light.

### CROSS-REFERENCE TO RELATED APPLICATIONS

This application is based on and claims priority under 35 USC 119 from Japanese Patent Application No. 2023-210099 filed Dec. 13, 2023.

### BACKGROUND

### (i) Technical Field

The present invention relates to a light emitting device and a distance measurement apparatus.

### (ii) Related Art

JP2020-160044A discloses a distance measurement apparatus including a light source having light emitting regions arranged in two dimensions, and a light receiving unit that receives reflected light reflected by a distance measurement target existing in a distance measurement region, in which preliminary light emission is performed by simultaneously emitting light beams from light emitting points of the light source at the same light intensity, and an intensity of light emitted by regular light emission is controlled based on an intensity of light received in each light reception region measured by a region light intensity measurement unit through the preliminary light emission.

JP2021-071478A discloses a detection apparatus including a light source device that divides an irradiation region of a detection target with light beams from a plurality of light emitting units into a plurality of irradiation regions and irradiates the detection target with the light beams, a light source drive unit that switches a plurality of illumination levels for each of the plurality of irradiation regions, and a control unit that integrates/combines a plurality of detection data related to the detection target detected by switching the plurality of illumination levels for each of the plurality of irradiation regions.

### SUMMARY

There is a distance measurement apparatus that measures a distance to a target object by a so-called time of flight (ToF) method in which a time from emission of light from a light emitting unit to reception of the light reflected by the target object by a light receiving unit is measured. In such a distance measurement apparatus, there is an aspect in which the light emitting unit is designed such that, in a case where a plurality of light sources are turned on, irradiation regions of the respective light sources can be arranged to be parallel to each other or superimposed on each other to irradiate a combined region with light. In such an aspect, the shift of the irradiation region of each light source increases depending on the distance to the target object, which may affect the distance measurement.

Aspects of non-limiting embodiments of the present disclosure relate to a light emitting device and a distance measurement apparatus that suppress an influence of the shift of an irradiation region of each light source as compared with a case where all light sources are turned on regardless of a distance.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting device including a light emitting unit that has a first light source irradiating a first irradiation region with light and a second light source irradiating a second irradiation region with light in a turned-on state and that arranges the first irradiation region and the second irradiation region to be parallel to each other or superimposed on each other at a reference distance and irradiates the first irradiation region and the second irradiation region with light, and a drive unit that drives the light emitting unit such that one of the first light source and the second light source is in a turned-on state and the other is in a turned-off state in a case where the light emitting unit irradiates a target object at a first distance different from the reference distance with light.

### BRIEF DESCRIPTION OF THE DRAWINGS

Exemplary embodiment(s) of the present invention will be described in detail based on the following figures, wherein:

FIG. 1 is a block diagram showing an example of a schematic configuration of a distance measurement apparatus to which the present exemplary embodiment is applied;

FIG. 2 is a diagram showing light sources included in a light emitting unit according to the present exemplary embodiment and irradiation regions which are regions that are irradiated with light beams emitted from the light sources;

FIG. 3 is a diagram showing the light sources included in the light emitting unit according to the present exemplary embodiment and irradiation surfaces that are irradiated with light beams emitted from the light sources;

FIGS. 4A and 4B are diagrams showing an irradiation surface in a case where one of light sources is in a turned-on state and the other is in a turned-off state;

FIG. 5 is a diagram showing a light source included in the light emitting unit according to Exemplary Embodiment 2 and an irradiation surface that is irradiated with light emitted from the light source;

FIGS. 6A and 6B are diagrams showing irradiation regions which are regions that are irradiated with light beams from the light sources;

FIG. 7 is a diagram describing an example of a configuration of a light receiving unit to which Exemplary Embodiment 2 is applied, and showing a light receiving surface of the light receiving unit and the above-described irradiation surface;

FIGS. 8A and 8B are diagrams showing an example of a state of the irradiation surface in a case where the light sources are driven such that sections adjacent to each other are irradiated with light beams at different timings;

FIGS. 9A and 9B are diagrams describing irradiation regions of the light sources on an irradiation surface whose distance in a +z direction from the light emitting unit is a distance shorter than a reference distance;

FIGS. 10A and 10B are diagrams describing an overlap between irradiation regions by the light sources on the irradiation surface;

FIG. 11 is a diagram describing an example of drive control of the light emitting unit by a light emission drive unit at a third timing;

FIGS. 12A to 12C are diagrams describing configurations of light sources included in the light emitting unit according to Exemplary Embodiment 3;

FIG. 13 is a diagram showing a light source included in the light emitting unit according to Exemplary Embodiment 3 and an irradiation surface that is irradiated with light emitted from the light source;

FIG. 14 is a diagram showing light sources included in the light emitting unit according to Exemplary Embodiment 4 and irradiation regions which are regions that are irradiated with light beams emitted from the light sources;

FIG. 15 is a diagram describing configurations of the light sources included in the light emitting unit according to Exemplary Embodiment 4; and

FIGS. 16A and 16B are diagrams describing an irradiation surface.

### DETAILED DESCRIPTION

Hereinafter, exemplary embodiments of the present invention will be described in detail with reference to the accompanying drawings.

The technical scope of the present invention is not limited to the scope to be described below as an exemplary embodiment. It is clear from the description of the claims that a combination of a plurality of examples and various modifications or improvements to the exemplary embodiment described above are also included in the technical scope of the present invention.

### Exemplary Embodiment 1

### Distance Measurement Apparatus 1

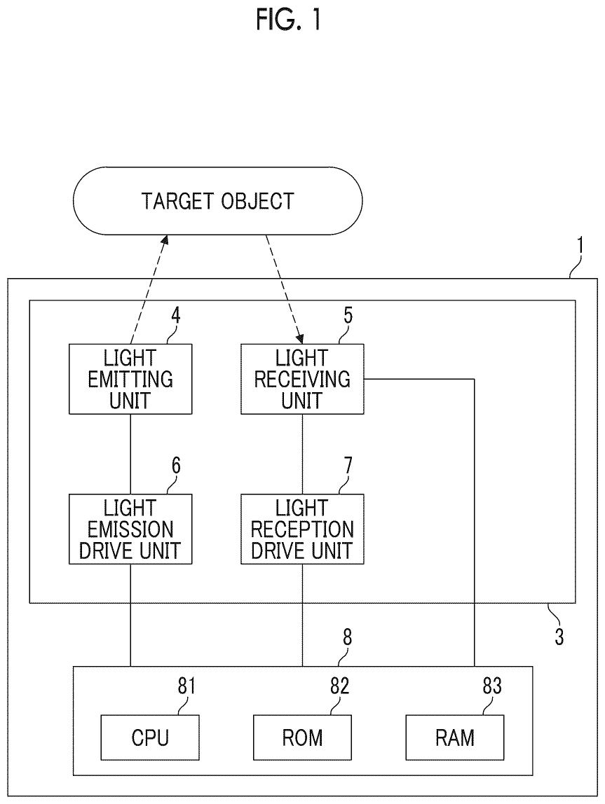

FIG. 1 is a block diagram showing an example of a schematic configuration of a distance measurement apparatus 1 to which the present exemplary embodiment is applied.

The distance measurement apparatus 1 measures a distance to a target object based on a time from a timing at which light is emitted from a light emitting unit 4 to a timing at which the light reflected by the target object is received by a light receiving unit 5. That is, the distance measurement apparatus 1 is an apparatus that performs distance measurement based on a ToF method. The ToF method includes an indirect ToF (iToF) method in which a time is measured from a difference between a phase of emitted light and a phase of received light, and a direct ToF (dToF) method in which a time from emission to reception of light is directly measured, and both methods can be adopted. In the present exemplary embodiment, description will be made assuming that the distance measurement apparatus 1 performs distance measurement based on the indirect ToF method.

As shown in FIG. 1, the distance measurement apparatus 1 includes an optical device 3 and a control unit 8.

The optical device 3 includes the light emitting unit 4 that emits light toward a predetermined region, the light receiving unit 5 that receives light reflected by the target object existing in an irradiation region of the light emitted from the light emitting unit 4, a light emission drive unit 6 that drives the light emitting unit 4, and a light reception drive unit 7 that drives the light receiving unit 5. The light emitting unit 4 is an example of a light emitting device. The light emission drive unit 6 is an example of a drive unit.

### Control Unit 8

The control unit 8 controls the operations of the light emitting unit 4 and the light receiving unit 5 of the optical device 3.

In addition, the control unit 8 acquires a result of the light reception by the light receiving unit 5, and measures a distance from the distance measurement apparatus 1 to the target object by the ToF method based on a result of the light reception.

The control unit 8 is an example of a calculation unit.

The control unit 8 is configured of a central processing unit (CPU) 81, a read only memory (ROM) 82, and a random access memory (RAM) 83.

The CPU 81 is an example of a processor, and implements each function, which will be described below, by loading various programs stored in the ROM 82 or the like into the RAM 83 and executing the programs. The RAM 83 is a memory used as a work memory or the like of the CPU 81. The ROM 82 is a memory that stores various programs and the like executed by the CPU 81.

Here, the program executed by the CPU 81 may be provided in a state of being stored in a computer-readable recording medium such as a magnetic recording medium (a magnetic tape, a magnetic disk, or the like), an optical recording medium (an optical disk or the like), a magneto-optical recording medium, or a semiconductor memory. In addition, the program executed by the CPU 81 may be provided by using a communication section such as the Internet.

In the embodiments above, the term “processor” refers to hardware in a broad sense. Examples of the processor include general processors (e.g., CPU: Central Processing Unit) and dedicated processors (e.g., GPU: Graphics Processing Unit, ASIC: Application Specific Integrated Circuit, FPGA: Field Programmable Gate Array, and programmable logic device).

In the embodiments above, the term “processor” is broad enough to encompass one processor or plural processors in collaboration which are located physically apart from each other but may work cooperatively. The order of operations of the processor is not limited to one described in the embodiments above, and may be changed.

### Light Emitting Unit 4

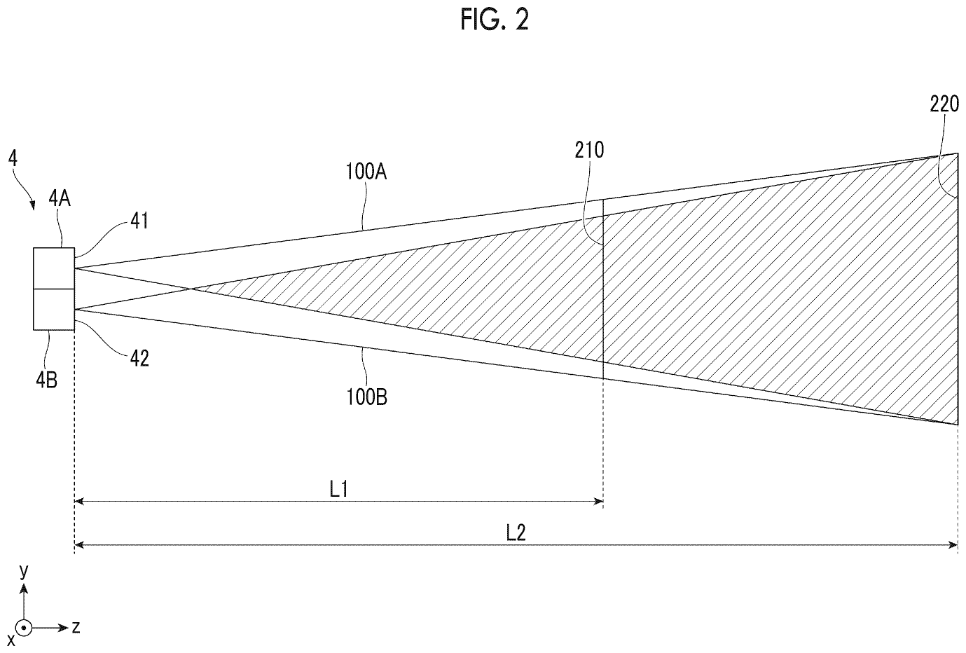

FIG. 2 is a diagram showing light sources 4A and 4B included in the light emitting unit 4 according to the present exemplary embodiment and irradiation regions 100A and 100B which are regions that are irradiated with light beams emitted from the light sources 4A and 4B. In the present exemplary embodiment, an example is shown in which the light emitting unit 4 has two light sources, but the number of the light sources included in the light emitting unit 4 may be three or more. As an example of an aspect in which the light emitting unit 4 has three or more light sources, Exemplary Embodiment 3 will be described below.

In FIG. 2, a front side of a paper plane is defined as a +x direction, an upper direction of the paper plane is defined as a +y direction, and a right direction of the paper plane is defined as a +z direction. Opposite directions of the directions are defined as −x, −y, and −z directions, respectively.

The light emitting unit 4 has the light source 4A that irradiates the irradiation region 100A with light and the light source 4B that irradiates the irradiation region 100B different from the irradiation region 100A with light. The light emitting unit 4 arranges the irradiation region 100A by the light source 4A and the irradiation region 100B by the light source 4B to be parallel to each other or superimposed on each other and irradiates the irradiation region 100A and irradiation region 100B. In this example, the light source 4A is an example of a first light source, the light source 4B is an example of a second light source, the irradiation region 100A is an example of a first irradiation region, and the irradiation region 100B is an example of a second irradiation region.

In the light emitting unit 4 according to the present exemplary embodiment, the light sources 4A and 4B are disposed to be parallel to each other in the y direction. In this example, the light source 4A is disposed on the +y direction side with respect to the light source 4B.

Here, the irradiation region 100A is a region that is irradiated with the light emitted from the light source 4A at a certain distance in the +z direction from the light emitting unit 4. Similarly, the irradiation region 100B is a region that is irradiated with the light emitted from the light source 4B at a certain distance in the +z direction from the light emitting unit 4.

The fact that the irradiation region 100A and the irradiation region 100B are parallel to each other means that the irradiation region 100A and the irradiation region 100B are arranged in a direction intersecting the z direction at a certain distance in the +z direction from the light emitting unit 4. In addition, the fact that the irradiation region 100A and the irradiation region 100B are superimposed on each other means that at least a partial region of the irradiation region 100A and at least a partial region of the irradiation region 100B overlap each other at a certain distance in the +z direction from the light emitting unit 4. In FIG. 2, a portion where the irradiation region 100A and the irradiation region 100B overlap each other is shown by hatching.

In the present exemplary embodiment, a distance from the light emitting unit 4 in the +z direction means, more accurately, a distance from a light emitting surface 41, which will be described below, of the light source 4A and a light emitting surface 42, which will be described below, of the light source 4B in the light emitting unit 4.

In addition, FIG. 2 shows irradiation surfaces 210 and 220 which are orthogonal to the +z direction and irradiated with the light beams of the irradiation regions 100A and 100B at a certain distance in the direction in which the light sources 4A and 4B emit the light (+z direction). The irradiation surfaces 210 and 220 extend in the x direction and the y direction at a certain distance in the +z direction. In addition, the irradiation surfaces 210 and 220 are arranged in order in the +z direction from the light sources 4A and 4B. Hereinafter, a distance in the +z direction from the light sources 4A and 4B to the irradiation surface 210 will be referred to as a distance L1, and a distance in the +z direction from the light sources 4A and 4B to the irradiation surface 220 will be referred to as a distance L2.

A relationship between the irradiation region 100A and the irradiation region 100B on the irradiation surfaces 210 and 220 will be described in detail below.

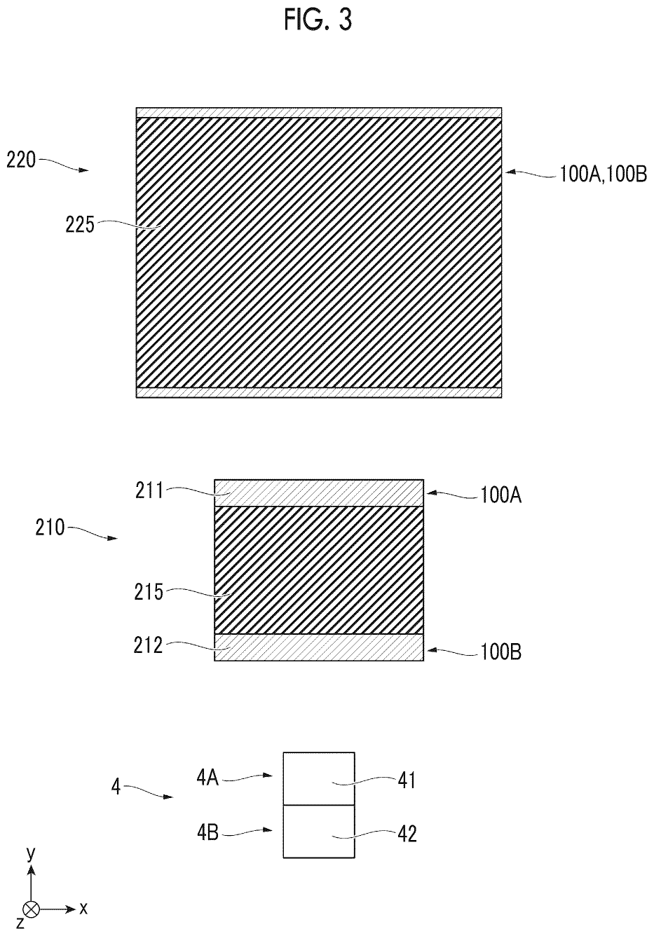

The light sources 4A and 4B have a light emitting surface in which a plurality of vertical cavity surface emitting lasers (VCSELs) are arranged. Hereinafter, the light emitting surface of the light source 4A will be referred to as a light emitting surface 41 (see FIG. 3 described below), and the light emitting surface of the light source 4B will be referred to as a light emitting surface 42 (see FIG. 3 described below).

Light beams emitted from the light sources 4A and 4B are spread and emitted onto a surface perpendicular to the emission direction by a diffusion unit (not shown) provided in the light sources 4A and 4B. As the diffusion unit, an optical member such as a diffusion plate that is provided on an optical path of the light to diffuse the light with scattering or the like, and a diffractive optical element (DOE) or/and a lens that changes an angle of the incident light and emits the light can be used.

The irradiation region 100A by the light source 4A and the irradiation region 100B by the light source 4B are expanded in the ±x direction and the ±y direction as it goes in the +z direction.

In the present exemplary embodiment, as shown in FIG. 2, in a region whose distance in the +z direction from the light sources 4A and 4B is less than the distance L2, the irradiation region 100A is located on the +y direction side with respect to the irradiation region 100B. In addition, in the present exemplary embodiment, as the distance from the light sources 4A and 4B increases, a ratio of the portion where the irradiation region 100A and the irradiation region 100B overlap each other to a combined region of the irradiation region 100A and the irradiation region 100B increases.

In the light emitting unit 4 according to the present exemplary embodiment, the light sources 4A and 4B are independently driven by the light emission drive unit 6 (see FIG. 1) to perform a light emission operation. It should be noted that the light sources 4A and 4B emit light by supplying power to the VCSEL included in the light sources 4A and 4B by the light emission drive unit 6.

The intensity of light of the VCSEL included in the light sources 4A and 4B changes depending on the magnitude of a value of a current flowing through the VCSEL in a case of being supplied with power. That is, as the power supplied to the light sources 4A and 4B increases and the value of the current flowing through the VCSEL increases, the intensity of light emitted from the VCSEL increases. In the following description, the current value of the VCSEL constituting the light sources 4A and 4B may be simply referred to as the current value of the light sources 4A and 4B.

Here, the phrase “independently driven” refers to a state in which light is emitted by driving each of the light sources 4A and 4B. The light emission drive unit 6 drives each of the light sources 4A and 4B in response to a control signal from the control unit 8 (see FIG. 1). Therefore, the light source 4A and the light source 4B do not necessarily emit light simultaneously. For example, the light source 4A can emit light while the light source 4B does not emit light. In the present exemplary embodiment, a state in which the light sources 4A and 4B emit light may be referred to as a turned-on state of the light sources 4A and 4B, and a state in which the light sources 4A and 4B do not emit light may be referred to as a turned-off state of the light sources 4A and 4B. The switching of the light sources 4A and 4B between the turned-on state and the turned-off state will be described in detail below.

FIG. 3 is a diagram showing the light sources 4A and 4B included in the light emitting unit 4 according to the present exemplary embodiment and irradiation surfaces 210 and 220 that are irradiated with light beams emitted from the light sources 4A and 4B. In FIG. 3, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. In FIG. 3, the light emitting unit 4 and the irradiation surfaces 210 and 220 are shown to be shifted in an up-down direction (±y direction), but in reality, the light emitting unit 4 and the irradiation surfaces 210 and 220 are disposed to face each other. In FIG. 3, the light emitting unit 4 is located in a front side direction (−z direction) of the paper plane, and the irradiation surface 210 and the irradiation surface 220 are located in a back side direction (+z direction) of the paper plane in this order. That is, FIG. 3 is a view of the light emitting unit 4 that emits light as viewed from a side opposite to a side on which the light emitting unit 4 emits light.

In the irradiation surfaces 210 and 220 of FIG. 3, a portion where the irradiation region 100A by the light source 4A and the irradiation region 100B by the light source 4B overlap each other is shown by hatching.

As shown in FIG. 3, in the light emitting unit 4, the light emitting surface 41 of the light source 4A and the light emitting surface 42 of the light source 4B are arranged to be parallel to each other in the y direction. In this example, the light emitting surface 41 of the light source 4A is parallel to the light emitting surface 42 of the light source 4B on the +y direction side.

In addition, a shape of each of the light emitting surface 41 and the light emitting surface 42 as viewed in the z direction is a rectangular shape having sides extending in the x direction and the y direction. It should be noted that, in the present exemplary embodiment, the light emitting surface 41 and the light emitting surface 42 have the same shape and area as viewed in the +z direction.

As described above, the light emitting unit 4 according to the present exemplary embodiment spreads and emits the light beams emitted from the light sources 4A and 4B onto a plane perpendicular to the emission direction. Therefore, the area of the irradiation surfaces 210 and 220 increases in the order of the irradiation surface 210 and the irradiation surface 220 arranged in the +z direction.

In addition, the shapes of the irradiation region 100A and the irradiation region 100B on the irradiation surfaces 210 and 220 are substantially rectangular shapes corresponding to the shapes of the light emitting surface 41 and the light emitting surface 42.

The light emitting unit 4 according to the present exemplary embodiment emits light such that the overlap between the irradiation region 100A by the light source 4A and the irradiation region 100B by the light source 4B is increased on the irradiation surface 220 at the distance L2 in the +z direction from the light emitting unit 4. The distance L2 is an example of a reference distance. Hereinafter, the distance L2 may be referred to as a reference distance L2.

In this example, the light emitting unit 4 emits light such that the entire irradiation region 100A by the light source 4A and substantially the entire irradiation region 100B by the light source 4B are superimposed on each other on the irradiation surface 220. In other words, in a case where both the light source 4A and the light source 4B are in a turned-on state, substantially the entire region of the irradiation surface 220 becomes an overlapping region 225 which is irradiated with the light from the light source 4A and the light from the light source 4B in a superimposed manner.

In the irradiation surface 220, the entire irradiation region 100A and the entire irradiation region 100B are superimposed on each other, so that the shape of the irradiation surface 220 as viewed in the +z direction is close to a rectangular shape corresponding to the shapes of the light emitting surface 41 of the light source 4A and the light emitting surface 42 of the light source 4B.

In the following description, the shape of the irradiation surface 220 as viewed in the +z direction may be referred to as a reference shape.

In addition, in the irradiation surface 210 whose distance in the +z direction from the light emitting unit 4 is the distance L1 shorter than the reference distance L2, the overlap between the irradiation region 100A by the light source 4A and the irradiation region 100B by the light source 4B is smaller than that in the irradiation surface 220. The distance L1 is an example of a first distance.

It should be noted that the light emitting unit 4 emits light such that the irradiation region 100A by the light source 4A and the irradiation region 100B by the light source 4B are arranged to be shifted in a direction intersecting the z direction on the irradiation surface 210. As a result, in the irradiation surface 210, a ratio of the portion where the irradiation region 100A and the irradiation region 100B overlap each other is more than 50%, and a ratio of the portion where the irradiation region 100A and the irradiation region 100B do not overlap each other is also 10% or more. In addition, a light intensity distribution on the irradiation surface 210 is non-uniform.

In this example, the light emitting unit 4 emits light such that the irradiation region 100A is arranged to be shifted in the +y direction with respect to the irradiation region 100B on the irradiation surface 210. As a result, in the irradiation surface 210, a partial region on the −y direction side in the irradiation region 100A and a partial region on the +y direction side in the irradiation region 100B overlap each other. In other words, the irradiation surface 210 includes an irradiation region 211 which is irradiated with the light from the light source 4A and is not irradiated with the light from the light source 4B, an irradiation region 212 which is irradiated with the light from the light source 4B and is not irradiated with the light from the light source 4A, and an overlapping region 215 which is irradiated with the light from the light source 4A and the light from the light source 4B in a superimposed manner, in a case where both the light source 4A and the light source 4B are in a turned-on state. In the irradiation surface 210, the irradiation region 211, the overlapping region 215, and the irradiation region 212 are arranged in this order in the −y direction.

In addition, the irradiation surface 210 has the irradiation region 100A and the irradiation region 100B arranged to be shifted in the y direction, so that the shape of the irradiation surface 210 as viewed in the +z direction is a rectangular shape having a larger ratio of the length in the y direction to the length in the x direction than the reference shape described above.

In addition, although not shown, the light emitting unit 4 emits light such that a proportion of a portion where the irradiation region 100A by the light source 4A and the irradiation region 100B by the light source 4B overlap each other is slightly increased with respect to the irradiation surface 220 at the reference distance L2 on the irradiation surface whose distance in the +z direction from the light emitting unit 4 is longer than the reference distance L2. In this example, the light emitting unit 4 emits the light on the irradiation surface whose distance in the +z direction from the light emitting unit 4 is longer than the reference distance L2 such that the irradiation region 100A is arranged to be shifted in the −y direction with respect to the irradiation region 100B.

### Light Receiving Unit 5

The light receiving unit 5 includes a light receiving surface that extends in the x direction and the y direction and in which a plurality of light receiving elements are arranged. Then, the light receiving unit 5 receives the light beams emitted from the light sources 4A and 4B of the light emitting unit 4 and reflected by the target object, by each light receiving element of the light receiving surface. Then, the light receiving unit 5 outputs an electrical signal corresponding to the light received by the light receiving element to the control unit 8.

Examples of the light receiving element include a photodiode or a phototransistor.

### Drive Control of Light Emitting Unit 4

Subsequently, the drive of the light emitting unit 4 performed by the light emission drive unit 6 based on the control by the control unit 8 will be described.

As described above, in a case where the distance in the +z direction from the light emitting unit 4 is different from the reference distance L2, the irradiation region 100A by the light source 4A and the irradiation region 100B by the light source 4B may be shifted from each other, which may affect the measurement of the distance to the target object.

For example, the irradiation surface 210 whose distance in the +z direction from the light emitting unit 4 is the distance L1 shorter than the reference distance L2 includes the irradiation region 211 which is irradiated with the light from the light source 4A and is not irradiated with the light from the light source 4B, the irradiation region 212 which is irradiated with the light from the light source 4B and is not irradiated with the light from the light source 4A, and the overlapping region 215 which is irradiated with the light from the light source 4A and the light from the light source 4B in a superimposed manner. In a case where both the light source 4A and the light source 4B are in a turned-on state, the intensity of light emitted from the light emitting unit 4 is non-uniform between the irradiation regions 211 and 212 and the overlapping region 215 in the irradiation surface 210. More specifically, in the irradiation surface 210, the overlapping region 215 is irradiated with the light beams from both the light source 4A and the light source 4B, so that the intensity of light emitted to the overlapping region 215 is larger than the intensity of light emitted to the irradiation regions 211 and 212.

In a case where both the light source 4A and the light source 4B are in a turned-on state, the intensity of light emitted to the target object is excessive in a case where the target object exists in the overlapping region 215 of the irradiation surface 210. In this case, for example, signal saturation may occur in a light receiving element of the light receiving unit 5 that receives the light reflected by the target object existing in the overlapping region 215, and the measurement of the distance to the target object may not be accurately performed.

On the other hand, the light emission drive unit 6 according to the present exemplary embodiment drives the light emitting unit 4 such that one of the light source 4A and the light source 4B is in a turned-on state and the other is in a turned-off state in a case where the light emitting unit 4 emits light to the target object at the distance L1 different from the reference distance L2.

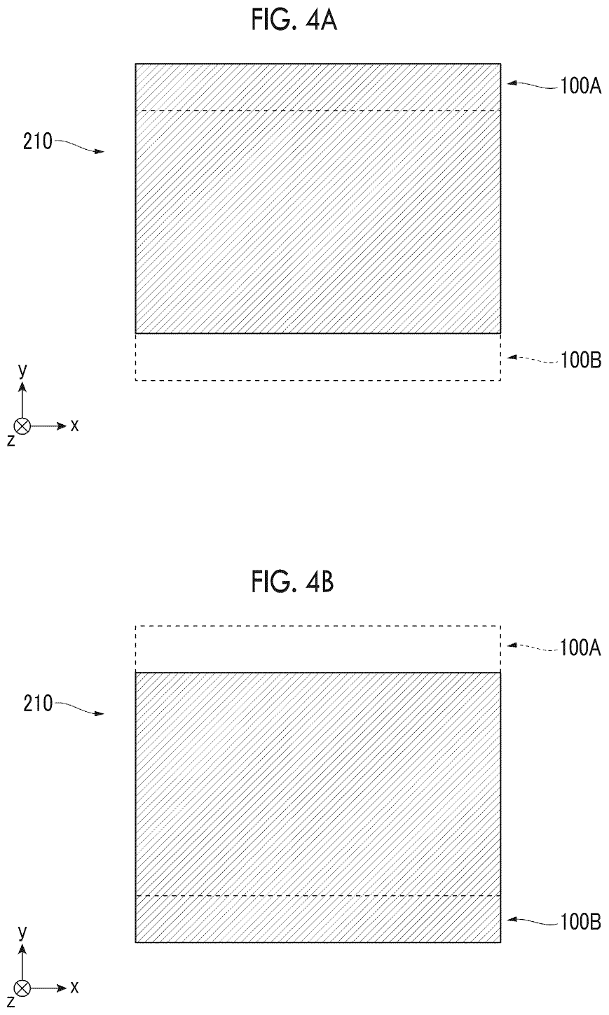

FIGS. 4A and 4B are diagrams showing the irradiation surface 210 in a case where one of the light source 4A and the light source 4B is in a turned-on state and the other is in a turned-off state. FIG. 4A shows the irradiation surface 210 in a case where the light source 4A is in a turned-on state and the light source 4B is in a turned-off state, and FIG. 4B shows the irradiation surface 210 in a case where the light source 4A is in a turned-off state and the light source 4B is in a turned-on state.

As shown in FIGS. 4A and 4B, in a case where one of the light source 4A and the light source 4B is in a turned-on state and the other is in a turned-off state, the overlapping region 215 (see FIG. 3) which is irradiated with the light from the light source 4A and the light from the light source 4B in a superimposed manner is not formed in the irradiation surface 210. As a result, the intensity of light emitted to the irradiation surface 210 is prevented from being non-uniform, and the intensity of light emitted to the target object is prevented from being excessive.

In addition, as shown in FIG. 4A, in a case where the light source 4A is in a turned-on state and the light source 4B is in a turned-off state, the shape of the irradiation surface 210 as viewed in the +z direction is a rectangular shape corresponding to the shape of the light emitting surface 41 (see FIG. 3) of the light source 4A. That is, in a case where the light source 4A is in a turned-on state and the light source 4B is in a turned-off state, the shape of the irradiation surface 210 as viewed in the +z direction is substantially equal to the reference shape.

Similarly, as shown in FIG. 4B, in a case where the light source 4A is in a turned-off state and the light source 4B is in a turned-on state, the shape of the irradiation surface 210 as viewed in the +z direction is a rectangular shape corresponding to the shape of the light emitting surface 42 (see FIG. 3) of the light source 4B. That is, in a case where the light source 4A is in a turned-off state and the light source 4B is in a turned-on state, the shape of the irradiation surface 210 as viewed in the +z direction is substantially equal to the reference shape.

Here, in a case where the target object whose distance in the +z direction from the light emitting unit 4 is the reference distance L2 is irradiated with the light, the light emission drive unit 6 may drive the light emitting unit 4 such that both the light source 4A and the light source 4B are in a turned-on state.

As described above, in the irradiation surface 220 whose distance in the +z direction from the light emitting unit 4 is the reference distance L2, in a case where both the light source 4A and the light source 4B are in a turned-on state, the entire irradiation region 100A by the light source 4A and the entire irradiation region 100B by the light source 4B are superimposed on each other. That is, in the irradiation surface 220, the entire region is the overlapping region 225 which is irradiated with the light from the light source 4A and the light from the light source 4B, and the intensity of light emitted from the light emitting unit 4 is uniform.

In this case, unlike the irradiation surface 210, the influence due to the non-uniformity in the intensity of light emitted from the light emitting unit 4 between the irradiation regions 211 and 212 and the overlapping region 215 is unlikely to occur.

Note that, in a case where a problem occurs even though the intensity of light is uniform, for example, in a case where a problem occurs because a target object with a high reflectivity, such as a mirror or a white board, exists on the irradiation surface and the light incident into the light receiving unit 5 is excessive, the light emitting unit 4 may be driven such that one of the light source 4A and the light source 4B is in a turned-on state and the other is in a turned-off state even in a case where the light is emitted to the target object existing at the reference distance L2.

The light emission drive unit 6 according to the present exemplary embodiment can drive the light emitting unit 4 such that one of the light source 4A and the light source 4B is in a turned-on state and the other is in a turned-off state in a case where the target object is detected at a distance different from the reference distance L2.

The control unit 8 detects the target object, for example, based on a light reception result obtained by the light receiving unit 5. As described above, at a distance (for example, the distance L1) different from the reference distance L2, the intensity of light emitted to the irradiation surface 210 may be non-uniform, and the intensity of light emitted to the target object may be excessive. In this case, the intensity of received light in the light receiving unit 5 that receives the light reflected by the target object increases. The control unit 8 detects the entry of the object into a distance different from the reference distance L2 in a case where the intensity of received light in the light receiving unit 5 exceeds a predetermined threshold value. As the threshold value of the intensity of received light used for the detection of the target object by the control unit 8, for example, the intensity of received light at which the signal saturation occurs in the light receiving element of the light receiving unit 5 can be used.

In addition, the control unit 8 may detect the entry of the target object into a distance (for example, the distance L1) different from the reference distance L2 using a detection sensor provided separately from the optical device 3.

In addition, for example, it is preferable that the light emission drive unit 6 according to the present exemplary embodiment does not change the magnitude of power supplied to the light sources 4A and 4B to be put into a turned-on state in a case where both the light source 4A and the light source 4B are in a turned-on state in order to emit light to the target object existing on the irradiation surface 220 and in a case where one of the light source 4A and the light source 4B is in a turned-on state and the other is in a turned-off state in order to emit light to the target object existing on the irradiation surface 210. In other words, for example, it is preferable that the light emission drive unit 6 switches the light sources 4A and 4B between the turned-on state and the turned-off state while fixing the current values of the light sources 4A and 4B.

Here, as another method for eliminating the problem of the excessive intensity of light emitted to the target object in the overlapping region 215 of the irradiation surface 210, for example, a method of decreasing the current values of the light sources 4A and 4B while keeping both the light sources 4A and 4B in a turned-on state is considered. In this case, by decreasing the current values, the intensity of light beams emitted from the light sources 4A and 4B is reduced, and the intensity of light emitted to the target object in the overlapping region 215 is reduced.

However, in general, in a case where the current values of the light sources 4A and 4B are changed, conditions such as a rise time and a fall time in a case where light is emitted from the light sources 4A and 4B are changed. Therefore, in order to accurately perform the distance measurement using the light beams emitted from the light sources 4A and 4B, it is necessary to set a correction parameter for correcting a control signal for driving the light sources 4A and 4B for each current value of the light sources 4A and 4B. In this case, the drive control of the light sources 4A and 4B, which is performed by the light emission drive unit 6 based on the control signal from the control unit 8, is likely to be complicated.

On the other hand, the light emission drive unit 6 according to the present exemplary embodiment switches the light sources 4A and 4B between a turned-on state and a turned-off state while fixing the current value of the VCSEL constituting the light sources 4A and 4B, thereby preventing the drive of the light sources 4A and 4B by the light emission drive unit 6 from being complicated.

In the present exemplary embodiment, for example, it is preferable that, in a case where one of the light source 4A and the light source 4B is in a turned-on state and the other is in a turned-off state, the control unit 8 determines as to which one of the light source 4A and the light source 4B is to be put into the turned-on state and which one is to be put into the turned-off state, based on a turning-on history of the light source 4A and the light source 4B. As a result, in a case where one of the light source 4A and the light source 4B is in a turned-on state and the other is in a turned-off state, the drive of the light emitting unit 4 can be controlled according to the turned-on state of the light source 4A and 4B and the turned-off state of the light source 4A and 4B, as compared with a case where the light source 4A and 4B to be put into the turned-on state and into the turned-off state are fixed.

Here, the turning-on history means a situation in which the light sources 4A and 4B are switched to a turned-on state or a turned-off state before the control of putting one of the light source 4A and the light source 4B into a turned-on state and putting the other into a turned-off state.

The control unit 8 can determine as to which one of the light source 4A and the light source 4B is to be put into the turned-on state and which one is to be put into the turned-off state based on a total turning-on time of the light source 4A and the light source 4B, as an example of the turning-on history of the light source 4A and the light source 4B. More specifically, in a case where one of the light source 4A and the light source 4B is in a turned-on state and the other is in a turned-off state, the control unit 8 causes the light emission drive unit 6 to drive the light emitting unit 4 such that one of the light source 4A and the light source 4B, which has a shorter total turning-on time, is in a turned-on state and the other, which has a longer total turning-on time, is in a turned-off state. As a result, in a case where one of the light source 4A and the light source 4B is in a turned-on state and the other is in a turned-off state, deviation in the total turning-on times of the light sources 4A and 4B is suppressed as compared with a case where the light source 4A and 4B to be put into the turned-on state and into the turned-off state are fixed.

In addition, as an example of the turning-on history of the light source 4A and the light source 4B, the control unit 8 can determine as to which one of the light source 4A and the light source 4B is to be put into the turned-on state and which one is to be put into the turned-off state based on a turning-on situation of the light source 4A and the light source 4B immediately before one of the light source 4A and the light source 4B is in a turned-on state and the other is in a turned-off state. For example, in a case where one of the light source 4A and the light source 4B is in a turned-on state and the other is in a turned-off state, the control unit 8 causes the light emission drive unit 6 to drive the light emitting unit 4 such that one of the light source 4A and the light source 4B, which has a shorter last turning-on time, is in a turned-on state and the other, which has a longer last turning-on time, is in a turned-off state.

Here, in a case where the light sources 4A and 4B are in a turned-on state, heat may be generated due to the light emission of the VCSEL. In addition, as the duration of the turned-on state of the light sources 4A and 4B is longer, a temperature of the light sources 4A and 4B increases due to the heat generated by the light emission of the VCSEL, which may affect the light emission efficiency. On the other hand, determination as to which one of the light source 4A and the light source 4B is to be put into the turned-on state and which one is to be put into the turned-off state is made based on a turning-on situation of the light source 4A and the light source 4B immediately before one of the light source 4A and the light source 4B is in a turned-on state and the other is in a turned-off state, thereby suppressing the influence of the heat generation on the light emission efficiency.

In the present exemplary embodiment, a case where the light emitting unit 4 includes two light sources 4A and 4B has been described as an example, but the number of the light sources included in the light emitting unit 4 is not limited to two, and the light emitting unit 4 may have three or more light sources provided such that the irradiation regions are superimposed on each other at the reference distance L2.

In addition, in a case where the light emitting unit 4 has three or more light sources, the light emission drive unit 6 may vary the number of light sources to be put into the turned-on state and the number of light sources to be put into the turned-off state according to the distance in the +z direction from the light emitting unit 4 where the target object exists. For example, the light emission drive unit 6 may reduce the number of light sources to be put into the turned-on state and increase the number of light sources to be put into the turned-off state as the distance from the light emitting unit 4 in the +z direction where the target object exists is shorter.

### Another Aspect of Drive Control of Light Emitting Unit 4

Subsequently, another aspect of the drive of the light emitting unit 4 performed by the light emission drive unit 6 based on the control by the control unit 8 will be described.

In the above description, a case has been described in which the light emission drive unit 6 drives the light emitting unit 4 such that one of the light source 4A and the light source 4B is in a turned-on state and the other is in a turned-off state in a case where the light emitting unit 4 emits light to the target object at a distance (for example, the distance L1) different from the reference distance L2.

The light emission drive unit 6 may drive the light emitting unit 4 by switching between the following first mode and second mode regardless of an actual distance from the light emitting unit 4 of the target object.

The first mode is a mode in which the target object at the first distance different from the reference distance L2 is irradiated with light and the light emitting unit 4 is driven such that one of the light source 4A and the light source 4B is in a turned-on state and the other is in a turned-off state. The first distance can be, for example, a distance shorter than the reference distance L2, and the distance L1 described above can be exemplified.

In addition, the second mode is a mode for irradiating the target object at a distance longer than the first distance with light, and is a mode in which the light emitting unit 4 is driven such that both the light source 4A and the light source 4B are in a turned-on state.

The light emission drive unit 6 can switch the light emitting unit 4 between the first mode and the second mode based on, for example, the distance from the light emitting unit 4 to the target object, which is detected by the control unit 8 based on the light reception result obtained by the light receiving unit 5.

It should be noted that the light emission drive unit 6 can drive the light emitting unit 4 in the first mode in a case where arrival of the target object at the first distance (for example, the distance L1) is predicted by the detection result of the target object. In this case, the target object that has arrived at the first distance may be prevented from being irradiated with light in a state in which the irradiation region 100A of the light source 4A and the irradiation region 100B of the light source 4B of the light emitting unit 4 are shifted from each other.

An example of the case where the arrival of the target object at the first distance is predicted is a case where the distance to the target object detected by the control unit 8 based on the light reception result obtained by the light receiving unit 5 approaches the first distance from a distance longer than the first distance as time elapses.

The switching of the light emitting unit 4 between the first mode and the second mode by the light emission drive unit 6 may be performed by an operation of a user who uses the distance measurement apparatus 1.

In addition, the aspect in which the light emitting unit 4 is switched between the first mode and the second mode by the light emission drive unit 6 may be applied to Exemplary Embodiment 2 and Exemplary Embodiment 3, which will be described below.

### Exemplary Embodiment 2

Hereinafter, Exemplary Embodiment 2 of the present invention will be described. In the distance measurement apparatus 1 according to Exemplary Embodiment 2, configurations of the light emitting unit 4 and the light receiving unit 5 included in the optical device 3 are different from the configuration of Exemplary Embodiment 1. In Exemplary Embodiment 2, the same configurations as the configurations in Exemplary Embodiment 1 are denoted by the same reference numerals, and the detailed description thereof will be omitted here.

### Light Emitting Unit 4

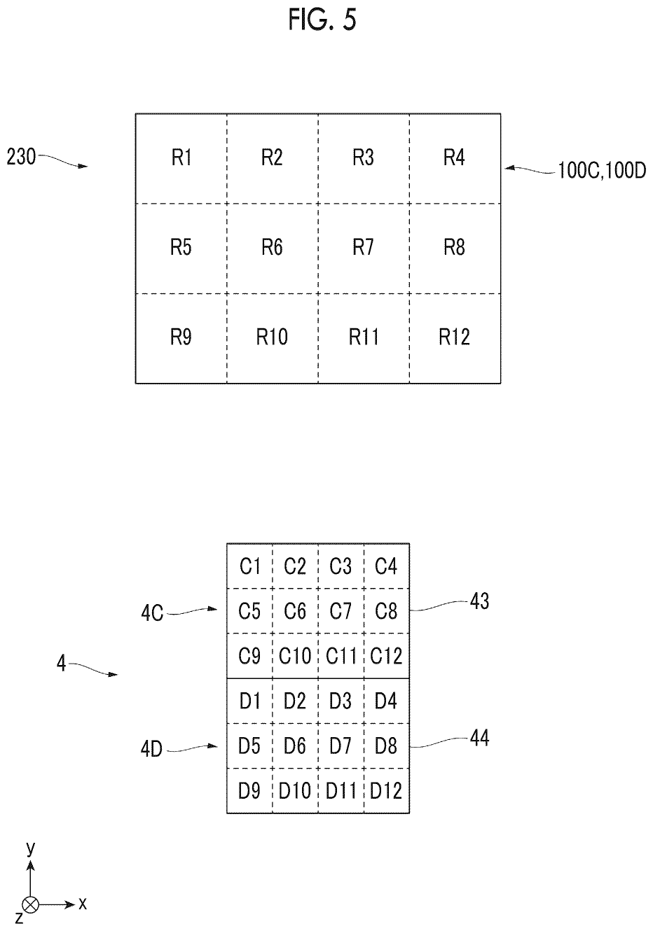

FIG. 5 is a diagram showing light sources 4C and 4D included in the light emitting unit 4 according to Exemplary Embodiment 2 and an irradiation surface 230 that is irradiated with light beams emitted from the light sources 4C and 4D. In FIG. 5, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. In FIG. 5, the light emitting unit 4 and the irradiation surface 230 are shown to be shifted in the up-down direction (±y direction), but in reality, the light emitting unit 4 and the irradiation surface 230 are disposed to face each other. In FIG. 5, the light emitting unit 4 is located in the front side direction (−z direction) of the paper plane, and the irradiation surface 230 is located in the back side direction (+z direction) of the paper plane. That is, FIG. 5 is a view of the light emitting unit 4 that emits light as viewed from a side opposite to a side on which the light emitting unit 4 emits light.

In addition, here, a distance in the +z direction from the light sources 4C and 4D to the irradiation surface 230 is the reference distance L2 (see FIG. 2) described above.

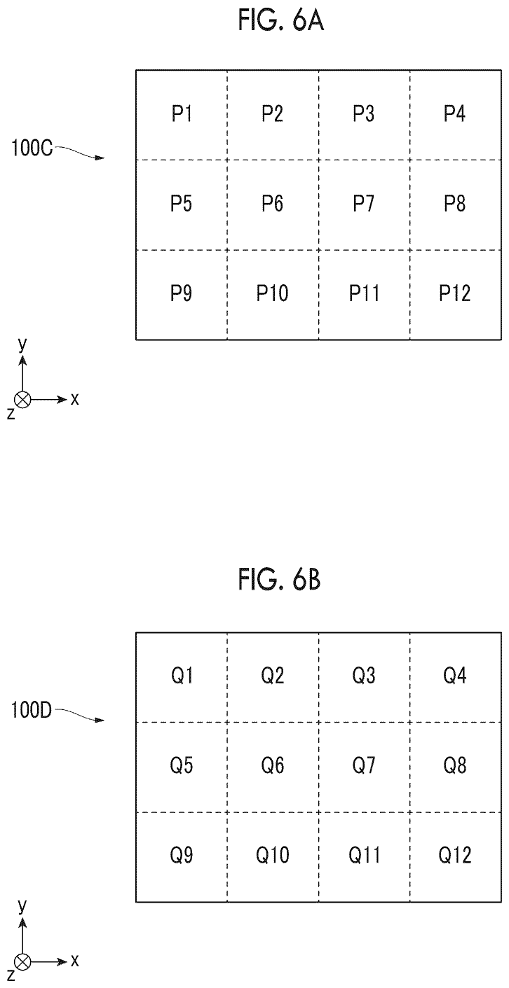

The light emitting unit 4 according to the present exemplary embodiment has the light source 4C that irradiates an irradiation region 100C (see FIGS. 6A to 6C described below) with light and the light source 4D that irradiates an irradiation region 100D (see FIGS. 6A to 6C described below) different from the irradiation region 100C with light. The light emitting unit 4 arranges the irradiation region 100C by the light source 4C and the irradiation region 100D by the light source 4D to be parallel to each other or superimposed on each other and irradiates the irradiation region 100C and irradiation region 100D with light. In this example, the light source 4C is an example of a first light source, the light source 4D is an example of a second light source, the irradiation region 100C is an example of a first irradiation region, and the irradiation region 100D is an example of a second irradiation region.

In the light emitting unit 4 according to the present exemplary embodiment, the light source 4C is disposed on the +y direction side with respect to the light source 4D.

The light sources 4C and 4D according to the present exemplary embodiment have light emitting surfaces 43 and 44 in which a plurality of VCSELs are arranged, respectively. In this example, the light emitting surface 43 of the light source 4C is parallel to the light emitting surface 44 of the light source 4D on the +y direction side.

Each of the light emitting surface 43 of the light source 4C and the light emitting surface 44 of the light source 4D is divided into a plurality of light emitting sections including at least one VCSEL. As an example, the light emitting surface 43 of the light source 4C is divided into a total of 12 light emitting sections C1 to C12 arranged in four rows in the x direction and three rows in the y direction. In this example, the light emitting sections C1 to C12 are located in order from the upper left (the end on the −x direction side and the +y direction side) to the lower right (the end on the +x direction side and the −y direction side) of the light emitting surface 43. Similarly, the light emitting surface 44 of the light source 4D is divided into a total of 12 light emitting sections D1 to D12 arranged in four rows in the x direction and three rows in the y direction. In this example, the light emitting sections D1 to D12 are located in order from the upper left (the end on the −x direction side and the +y direction side) to the lower right (the end on the +x direction side and the −y direction side) of the light emitting surface 44.

Each of the light emitting sections C1 to C12 of the light source 4C and each of the light emitting sections D1 to D12 of the light source 4D are independently driven by the light emission drive unit 6 to emit light. The light emission drive unit 6 drives each light emitting section of the light sources 4C and 4D in response to the control signal from the control unit 8. Therefore, the light emitting sections C1 to C12 of the light source 4C and the light emitting sections D1 to D12 of the light source 4D do not necessarily emit light simultaneously, and a state in which a part of the light emitting sections emits light and the rest of the light emitting sections do not emit light can be taken. In the present exemplary embodiment, a state in which each of the light emitting sections C1 to C12 of the light source 4C and each of the light emitting sections D1 to D12 of the light source 4D are emitting light is referred to as a turned-on state of the light emitting section. In addition, a state in which each of the light emitting sections C1 to C12 of the light source 4C and each of the light emitting sections D1 to D12 of the light source 4D are not emitting light is referred to as a turned-off state of the light emitting section.

FIGS. 6A and 6B are diagrams showing irradiation regions 100C and 100D which are regions that are irradiated with light beams from the light sources 4C and 4D. FIG. 6A shows the irradiation region 100C by the light source 4C, and FIG. 6B shows the irradiation region 100D by the light source 4D. FIGS. 6A and 6B are views showing the irradiation region 100C and the irradiation region 100D at a certain distance in the +z direction from the light emitting unit 4 as viewed in the +z direction.

As shown in FIG. 6A, the irradiation region 100C includes irradiation sections P1 to P12 that are irradiated with the light beams emitted from the light emitting sections C1 to C12 of the light source 4C. The irradiation sections P1 to P12 are located in order from the upper left (the end on the −x direction side and the +y direction side) to the lower right (the end on the +x direction side and the −y direction side) of the irradiation region 100C. In the irradiation region 100C, a certain irradiation section Pi (i=1 to 12) is irradiated with light emitted from the light emitting section Ci to which the same number i is assigned.

Shapes of the respective irradiation sections P1 to P12 of the irradiation region 100C are rectangular shapes corresponding to the shapes of the respective light emitting sections C1 to C12 of the light emitting surface 43. In addition, the shape of the entire irradiation region 100C is a rectangular shape corresponding to the shape of the light emitting surface 43.

As shown in FIG. 6B, the irradiation region 100D includes irradiation sections Q1 to Q12 that are irradiated with the light beams emitted from the light emitting sections D1 to D12 of the light source 4D. The irradiation sections Q1 to Q12 are located in order from the upper left (the end on the −x direction side and the +y direction side) to the lower right (the end on the +x direction side and the −y direction side) of the irradiation region 100D. In the irradiation region 100D, a certain irradiation section Qi (i=1 to 12) is irradiated with light emitted from the light emitting section Di to which the same number i is assigned.

Shapes of the respective irradiation sections Q1 to Q12 of the irradiation region 100D are rectangular shapes corresponding to the shapes of the respective light emitting sections D1 to D12 of the light emitting surface 44. In addition, the shape of the entire irradiation region 100D is a rectangular shape corresponding to the shape of the light emitting surface 44.

The light emitting unit 4 according to the present exemplary embodiment emits light such that the overlap between the irradiation region 100C by the light source 4C and the irradiation region 100D by the light source 4D is increased on the irradiation surface 230 whose distance in the +z direction from the light emitting unit 4 is the reference distance L2.

In this example, as shown in FIG. 5, the light emitting unit 4 emits light such that the entire irradiation region 100C by the light source 4C and the entire irradiation region 100D by the light source 4D are superimposed on each other on the irradiation surface 230. In this case, in the irradiation surface 230, the irradiation sections P1 to P12 (see FIG. 6A) of the irradiation region 100C by the light source 4C and the irradiation sections Q1 to Q12 (see FIG. 6B) of the irradiation region 100D by the light source 4D are superimposed on each other. It should be noted that, in the irradiation surface 230, the irradiation section Pi of the irradiation region 100C and the irradiation section Qi of the irradiation region 100D to which the same number i is assigned are superimposed on each other.

In addition, in the irradiation surface 230 according to the present exemplary embodiment, the irradiation section Pi of the irradiation region 100C and the irradiation section Qj of the irradiation region 100D to which the number j different from the number i is assigned are not superimposed on each other.

For example, in the irradiation surface 230, the irradiation section P1 of the irradiation region 100C and the irradiation section Q1 of the irradiation region 100D are superimposed on each other. On the other hand, in the irradiation surface 230, the irradiation section P1 of the irradiation region 100C and the irradiation sections Q2, Q5, and Q6 adjacent to the irradiation section Q1 in the irradiation region 100D are not superimposed on each other.

As a result, in the light emitting unit 4 according to the present exemplary embodiment, in a case where the light source 4C and the light source 4D are simultaneously turned on by the light emission drive unit 6, the irradiation surface 230 can be divided into a plurality of sections and irradiated with light by independently driving the light emitting sections C1 to C12 of the light source 4C and the light emitting sections D1 to D12 of the light source 4D.

In the following description, on the irradiation surface 230, a plurality of sections that can be divided and irradiated with light by the light sources 4C and 4D will be denoted by sections R1 to R12 of the irradiation surface 230. In the irradiation surface 230, in a case where the light emitting section Ci of the light source 4C and the light emitting section Di of the light source 4D are in a turned-on state, the section Ri having the same number i is irradiated with the light from the light emitting section Ci and the light from the light emitting section Di in a superimposed manner. That is, in the section Ri of the irradiation surface 230, the irradiation section Pi of the irradiation region 100C by the light source 4C and the irradiation section Qi of the irradiation region 100D by the light source 4D are superimposed on each other.

A relationship between the irradiation sections P1 to P12 of the irradiation region 100C by the light source 4C and the irradiation sections Q1 to Q12 of the irradiation region 100D by the light source 4D in an irradiation surface (irradiation surface 240 described below) whose distance in the +z direction from the light emitting unit 4 is different from the reference distance L2 will be described below.

### Light Receiving Unit 5

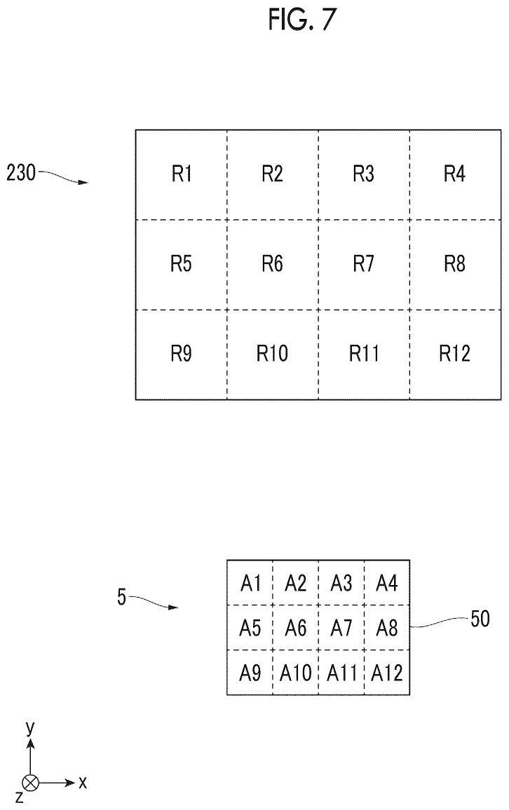

FIG. 7 is a diagram describing an example of a configuration of the light receiving unit 5 to which Exemplary Embodiment 2 is applied, and showing a light receiving surface 50 of the light receiving unit 5 and the above-described irradiation surface 230. In FIG. 7, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. In FIG. 7, the light receiving unit 5 and the irradiation surface 230 are shown to be shifted in the up-down direction (±y direction), but in reality, the light receiving unit 5 and the irradiation surface 230 are disposed to face each other. In FIG. 7, the light receiving unit 5 is located in the front side direction (−z direction) of the paper plane, and the irradiation surface 230 is located in the back side direction (+z direction) of the paper plane.

The light receiving unit 5 includes the light receiving surface 50 that extends in the x direction and the y direction and in which a plurality of light receiving elements are arranged.

The light receiving surface 50 is divided into a plurality of light receiving sections A1 to A12 corresponding to the sections R1 to R12 of the irradiation surface 230. Specifically, the light receiving surface 50 is divided into a total of 12 light receiving sections A1 to A12 arranged in four rows in the x direction and three rows in the y direction. In this example, the light receiving sections A1 to A12 are located in order from the upper left (the end on the −x direction side and the +y direction side) to the lower right (the end on the +x direction side and the −y direction side) of the light receiving surface 50.

Each of the light receiving sections A1 to A12 receives the light emitted from the light emitting sections C1 to C12 of the light source 4C and the light emitting sections D1 to D12 of the light source 4D and reflected by the target object existing in the section Ri having the same number. The light receiving sections A1 to A12 are independently driven by the light reception drive unit 7 (see FIG. 1) to perform a light receiving operation.

### Drive Control of Light Emitting Unit 4

Subsequently, the drive of the light emitting unit 4 performed by the light emission drive unit 6 based on the control by the control unit 8 will be described.

The light emission drive unit 6 according to the present exemplary embodiment drives the light source 4C and the light source 4D, for example, such that the sections R1 to R12 adjacent to each other among the sections R1 to R12 are irradiated with light beams at different timings on the irradiation surface 230. In other words, the light emission drive unit 6 drives the light source 4C and the light source 4D such that the light emitting sections C1 to C12 of the light source 4C and the light emitting sections D1 to D12 of the light source 4D, which emit light toward the sections R1 to R12 adjacent to each other among the sections R1 to R12, respectively, are driven to emit light at different timings on the irradiation surface 230.

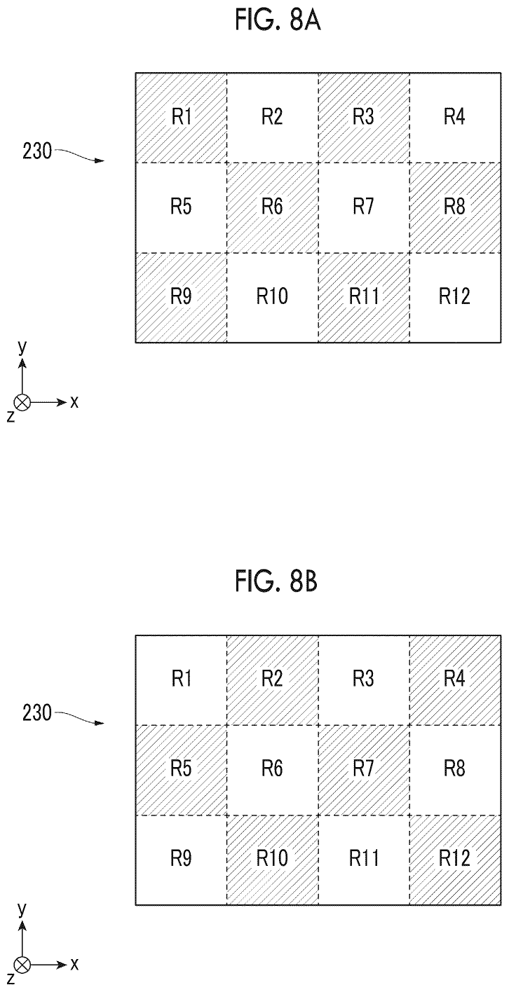

FIGS. 8A and 8B are diagrams showing an example of a state of the irradiation surface 230 in a case where the light source 4C and the light source 4D are driven such that sections Ri to R12 adjacent to each other are irradiated with light beams at different timings. In FIGS. 8A and 8B, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. In addition, in FIGS. 8A and 8B, among the sections R1 to R12 of the irradiation surface 230, the sections R1 to R12 that are irradiated with light beams from the light sources 4C and 4D are shown by hatching.

The light emission drive unit 6 drives the light sources 4C and 4D such that a group consisting of the sections R1, R3, R6, R8, R9, and R11 arranged in a meandering manner and a group consisting of the sections R2, R4, R5, R7, R10, and R12 are irradiated with light beams at different timings on the irradiation surface 230.

Specifically, at a predetermined first timing, the light emission drive unit 6 puts the light emitting sections C1, C3, C6, C8, C9, and C11 of the light source 4C into a turned-on state and puts the light emitting sections D1, D3, D6, D8, D9, and D11 of the light source 4D into a turned-on state, and puts the light emitting sections C2, C4, C5, C7, C10, and C12 of the light source 4C into a turned-off state and puts the light emitting sections D2, D4, D5, D7, D10, and D12 of the light source 4D into a turned-off state.

As a result, at the first timing, as shown in FIG. 8A, the sections R1, R3, R6, R8, R9, and R11 of the irradiation surface 230 are irradiated with the light beams emitted from the light emitting section C1, C3, C6, C8, C9, and C11 of the light source 4C and the light emitting section D1, D3, D6, D8, D9, and D11 of the light source 4D.

In a certain section Ri of the irradiation surface 230, as described above, the irradiation section Pi of the irradiation region 100C and the irradiation section Qi of the irradiation region 100D to which the same number i is assigned are superimposed on each other. On the other hand, in the section Ri, the irradiation section Pi of the irradiation region 100C and the irradiation section Qj of the irradiation region 100D to which the number j different from the number i is assigned are not superimposed on each other, and the irradiation section Qi of the irradiation region 100D and the irradiation section Pk of the irradiation region 100C to which the number k different from the number i is assigned are not superimposed on each other.

Therefore, at the first timing, the sections R2, R4, R5, R7, R10, and R12 of the irradiation surface 230 are not irradiated with the light beams emitted from the light emitting section C1, C3, C6, C8, C9, and C11 of the light source 4C and the light emitting section D1, D3, D6, D8, D9, and D11 of the light source 4D.

In addition, at a second timing different from the first timing, the light emission drive unit 6 puts the light emitting sections C2, C4, C5, C7, C10, and C12 of the light source 4C into a turned-on state and puts the light emitting sections D2, D4, D5, D7, D10, and D12 of the light source 4D into a turned-on state, and puts the light emitting sections C1, C3, C6, C8, C9, and C11 of the light source 4C into a turned-off state and puts the light emitting sections D1, D3, D6, D8, D9, and D11 of the light source 4D into a turned-off state.

As a result, at the second timing, as shown in FIG. 8B, the sections R2, R4, R5, R7, R10, and R12 of the irradiation surface 230 are irradiated with the light beams emitted from the light emitting section C2, C4, C5, C7, C10, and C12 of the light source 4C and the light emitting section D2, D4, D5, D7, D10, and D12 of the light source 4D.

In addition, at the second timing, the sections R1, R3, R6, R8, R9, and R11 of the irradiation surface 230 are not irradiated with the light beams emitted from the light emitting section C2, C4, C5, C7, C10, and C12 of the light source 4C and the light emitting section D2, D4, D5, D7, D10, and D12 of the light source 4D.

The second timing can be, for example, a timing following the first timing.

As described above, with the light emitting unit 4 according to the present exemplary embodiment, the group consisting of the sections R1, R3, R6, R8, R9, and R11 and the group consisting of the sections R2, R4, R5, R7, R10, and R12 adjacent to the group consisting of the sections R1, R3, R6, R8, R9, and R11 can be irradiated with light beams at different timings on the irradiation surface 230 whose distance in the +z direction from the light emitting unit 4 is the reference distance L2.

The light receiving unit 5 can acquire the light reception result for each of the sections R1 to R12 of the irradiation surface 230 by acquiring the light reflected by the irradiation surface 230 at different timings between a group consisting of the light receiving sections A1, A3, A6, A8, A9, and A11 and a group consisting of the light receiving sections A2, A4, A5, A7, A10, and A12. As a result, in the distance measurement apparatus 1 according to the present exemplary embodiment, the distance to the target object existing on the irradiation surface 230 can be accurately measured as compared with a case where the light emitting sections C1 to C12 of the light source 4C and the light emitting sections D1 to D12 of the light source 4D are simultaneously turned on and the sections R1 to R12 of the irradiation surface 230 are simultaneously irradiated with light beams.

Here, in Exemplary Embodiment 2, in a case where the distance in the +z direction from the light emitting unit 4 is different from the reference distance L2, the irradiation region 100C by the light source 4C and the irradiation region 100D by the light source 4D may be shifted from each other, which may affect the distance measurement of the target object, as in Exemplary Embodiment 1.

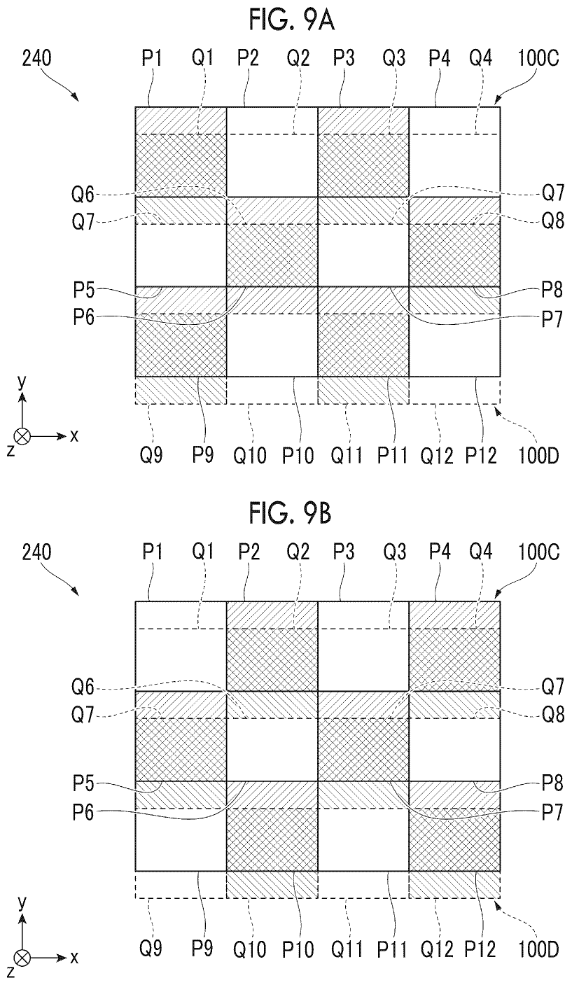

FIGS. 9A and 9B are diagrams describing the irradiation region 100C of the light source 4C and the irradiation region 100D of the light source 4D in the irradiation surface 240 whose distance in the +z direction from the light emitting unit 4 is the distance L1 (see FIG. 2) shorter than the reference distance L2. In FIGS. 9A and 9B, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. In addition, in FIGS. 9A and 9B, the irradiation region 100C of the light source 4C is shown by a solid line, and the irradiation region 100D of the light source 4D is shown by a broken line.

FIG. 9A shows a relationship between the irradiation sections P1, P3, P6, P8, P9, and P11 of the irradiation region 100C and the irradiation sections Q1, Q3, Q6, Q8, Q9, and Q11 of the irradiation region 100D in the irradiation surface 240. It should be noted that, in FIG. 9A, in a case where the light emitting sections C1, C3, C6, C8, C9, and C11 of the light source 4C and the light emitting sections D1, D3, D6, D8, D9, and D11 of the light source 4D are in a turned-on state, a portion which is irradiated with light on the irradiation surface 240 is shown by hatching.

FIG. 9B shows a relationship between the irradiation sections P2, P4, P5, P7, P10, and P12 of the irradiation region 100C and the irradiation sections Q2, Q4, Q5, Q7, Q10, and Q12 of the irradiation region 100D in the irradiation surface 240. It should be noted that, in FIG. 9B, in a case where the light emitting sections C2, C4, C5, C7, C10, and C12 of the light source 4C and the light emitting sections D2, D4, D5, D7, D10, and D12 of the light source 4D are in a turned-on state, a portion which is irradiated with light on the irradiation surface 240 is shown by hatching.

As shown in FIGS. 9A and 9B, the light emitting unit 4 according to the present exemplary embodiment emits light such that the irradiation region 100C of the light source 4C is arranged to be shifted with respect to the irradiation region 100D of the light source 4D in the +y direction on the irradiation surface 240.

In this case, in the irradiation surface 240, the irradiation section Pi of the irradiation region 100C and the irradiation section Qi of the irradiation region 100D to which the same number i is assigned are arranged to be shifted in the +y direction.

For example, as shown in FIG. 9A, in a case where the light emitting sections C1, C3, C6, C8, C9, and C11 of the light source 4C and the light emitting sections D1, D3, D6, D8, D9, and D11 of the light source 4D to which the same numbers are assigned are simultaneously turned on, the irradiation sections P1, P3, P6, P8, P9, and P11 and the irradiation sections Q1, Q3, Q6, Q8, Q9, and Q11 are arranged to be shifted in the y direction on the irradiation surface 240. In this case, in the irradiation surface 240, the irradiation sections P1, P3, P6, P8, P9, and P11 and the irradiation sections Q1, Q3, Q6, Q8, Q9, and Q11 are superimposed on each other in a partial region in the y direction, and are not superimposed on each other in a partial region in the y direction.

In addition, as shown in FIG. 9B, in a case where the light emitting sections C2, C4, C5, C7, C10, and C12 of the light source 4C and the light emitting sections D2, D4, D5, D7, D10, and D12 of the light source 4D to which the same numbers are assigned are simultaneously turned on, the irradiation sections P2, P4, P5, P7, P10, and P12 and the irradiation sections Q2, Q4, Q5, Q7, Q10, and Q12 are arranged to be shifted in the y direction on the irradiation surface 240. In this case, in the irradiation surface 240, the irradiation sections P2, P4, P5, P7, P10, and P12 and the irradiation sections Q2, Q4, Q5, Q7, Q10, and Q12 are superimposed on each other in a partial region in the y direction, and are not superimposed on each other in a partial region in the y direction.

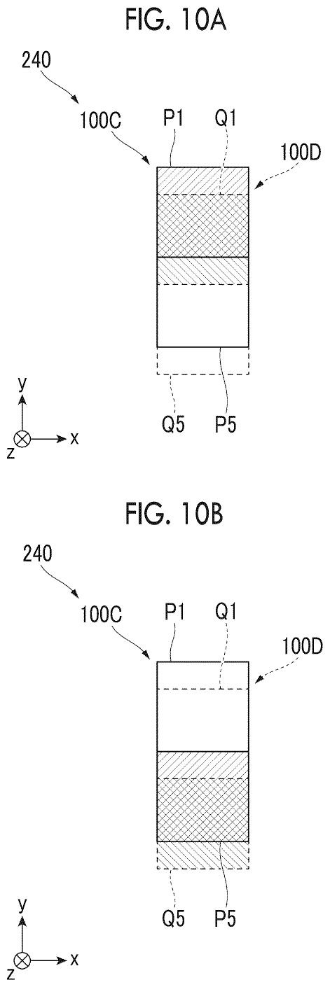

FIGS. 10A and 10B are diagrams describing an overlap between irradiation region 100C by the light source 4C and the irradiation region 100D by the light source 4D in the irradiation surface 240. In FIGS. 10A and 10B, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. In addition, in FIGS. 10A and 10B, the irradiation region 100C of the light source 4C is shown by a solid line, and the irradiation region 100D of the light source 4D is shown by a broken line.

In addition, FIGS. 10A and 10B show the irradiation sections P1 and P5 of the irradiation region 100C and the irradiation sections Q1 and Q5 of the irradiation region 100D, of the irradiation region 100C and the irradiation region 100D in the irradiation surface 240.

In FIG. 10A, the light emitting section C1 of the light source 4C and the light emitting section D1 of the light source 4D are in a turned-on state, and the light emitting section C5 of the light source 4C and the light emitting section D5 of the light source 4D are in a turned-off state.

In addition, in FIG. 10B, the light emitting section C5 of the light source 4C and the light emitting section D5 of the light source 4D are in a turned-on state, and the light emitting section C1 of the light source 4C and the light emitting section D1 of the light source 4D are in a turned-off state.

In FIGS. 10A and 10B, the irradiation sections P1 and P5 that are irradiated with light beams from the light emitting sections C1 and C5 of the light source 4C in a turned-on state, and the irradiation sections Q1 and Q5 that are irradiated with light beams from the light emitting sections D1 and D5 of the light source 4D in a turned-on state are shown by hatching.

As shown in FIGS. 10A and 10B, the light emitting unit 4 according to the present exemplary embodiment emits light such that the irradiation section P1 is arranged to be shifted with respect to the irradiation section Q1 in the +y direction on the irradiation surface 240. As a result, in the irradiation surface 240, a partial region on the −y direction side in the irradiation section P1 and a partial region on the +y direction side in the irradiation section Q1 are superimposed on each other.

Similarly, the light emitting unit 4 emits light such that the irradiation section P5 is arranged to be shifted in the +y direction with respect to the irradiation section Q5 on the irradiation surface 240. As a result, in the irradiation surface 240, a partial region on the −y direction side in the irradiation section P5 and a partial region on the +y direction side in the irradiation section Q5 are superimposed on each other.

In addition, on the irradiation surface 240, the irradiation section Q1 is arranged to be shifted in the −y direction with respect to the irradiation section P1, so that a partial region on the −y direction side in the irradiation section Q1 and a partial region on the +y direction side in the irradiation section P5 adjacent to the irradiation section P1 on the −y direction side are superimposed on each other.

Further, on the irradiation surface 240, the irradiation section P5 is arranged to be shifted in the +y direction with respect to the irradiation section Q5, so that a partial region on the +y direction side in the irradiation section P5 and a partial region on the −y direction side in the irradiation section Q1 adjacent to the irradiation section Q5 on the +y direction side are superimposed on each other.

Here, in the light emitting unit 4 according to Exemplary Embodiment 2, a case is considered in which, at a predetermined third timing, the light emitting section C1 of the light source 4C and the light emitting section D1 of the light source 4D are simultaneously turned on, and the light emitting section C5 of the light source 4C and the light emitting section D5 of the light source 4D are in a turned-off state. In this case, as shown in FIG. 10A, in the irradiation surface 240, since the irradiation section Q1 and the irradiation section P1 are superimposed on each other, the irradiation section P5, which is not irradiated with light by the light emitting sections C1 and C5 of the light source 4C, is irradiated with the light from the light emitting section D1 of the light source 4D.

In this example, the light emitting section C5 of the light source 4C is an example of a first light emitting section that irradiates the irradiation section P5, which is a first irradiation section, with light, and the light emitting section C1 of the light source 4C is an example of a third light emitting section that irradiates the irradiation section P1, which is a third irradiation section adjacent to the irradiation section P5, with light.

In addition, the light emitting section D5 of the light source 4D is an example of a second light emitting section that irradiates the irradiation section Q5, which is a second irradiation section, with light, and the light emitting section D1 of the light source 4D is an example of a fourth light emitting section that irradiates the irradiation section Q1, which is a fourth irradiation section adjacent to the irradiation section Q5, with light.

In addition, in the light emitting unit 4 according to Exemplary Embodiment 2, a case is considered in which, at a fourth timing different from the third timing, the light emitting section C5 of the light source 4C and the light emitting section D5 of the light source 4D are simultaneously turned on, and the light emitting section C1 of the light source 4C and the light emitting section D1 of the light source 4D are in a turned-off state. In this case, as shown in FIG. 10B, in the irradiation surface 240, the irradiation section Q1, which is not irradiated with light by the light emitting sections D1 and D5 of the light source 4D, is irradiated with the light from the light emitting section C5 of the light source 4C.

As described above, in the light emitting unit 4 according to Exemplary Embodiment 2, in a case where the light emitting section Ci of the light source 4C that irradiates the irradiation section Pi with light and the light emitting section Di of the light source 4D that irradiates the irradiation section Qi having the same number with light are simultaneously turned on, the irradiation section Pj adjacent to the irradiation section Pi in the −y direction is irradiated with light even in a case where the light emitting section Cj of the light source 4C that irradiates the irradiation section Pj with light is in a turned-off state.

In this case, in the irradiation surface 240, it is difficult to irradiate the irradiation sections Pi and Qi and the irradiation sections Pj and Qj adjacent to the irradiation sections Pi and Qi with light beams at different timings, unlike the irradiation surface 230 having the reference distance L2.

Therefore, the light emission drive unit 6 according to the present exemplary embodiment drives the light emitting unit 4 such that one of the light emitting section Ci of the light source 4C that irradiates the irradiation section Pi with light and the light emitting section Di of the light source 4D that irradiates the irradiation section Qi having the same number with light is in a turned-on state and the other is in a turned-off state at the predetermined third timing at the distance L1 different from the reference distance L2. At the third timing, the light emission drive unit 6 drives the light emitting unit 4 such that the light emitting section Cj of the light source 4C that irradiates the irradiation section Pj adjacent to the irradiation section Pi with light and the light emitting section Dj of the light source 4D that irradiates the irradiation section Qj adjacent to the irradiation section Qi with light are in a turned-off state.

In addition, at the fourth timing different from the third timing, the light emission drive unit 6 drives the light emitting unit 4 such that one of the light emitting section Cj of the light source 4C that irradiates the irradiation section Pj adjacent to the irradiation section Pi with light and the light emitting section Dj of the light source 4D that irradiates the irradiation section Qj adjacent to the irradiation section Qi with light is in a turned-on state and the other is in a turned-off state. At the fourth timing, the light emission drive unit 6 drives the light emitting unit 4 such that the light emitting section Ci of the light source 4C that irradiates the irradiation section Pi with light and the light emitting section Di of the light source 4D that irradiates the irradiation section Qi with light are in a turned-off state.

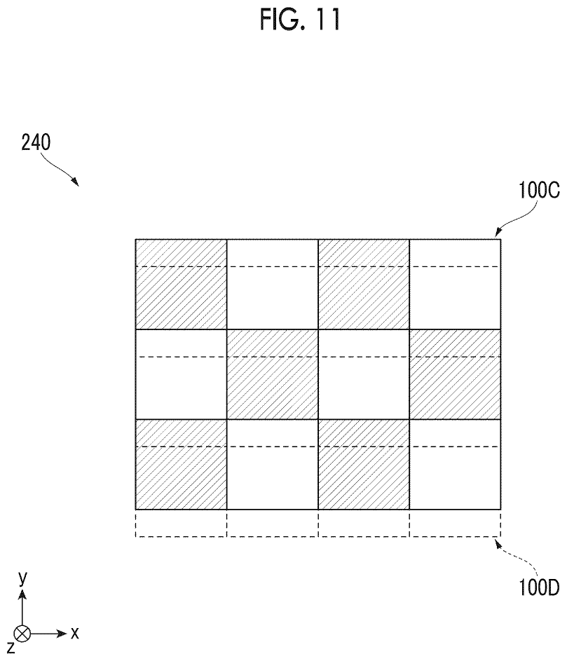

FIG. 11 is a diagram describing an example of drive control of the light emitting unit 4 by the light emission drive unit 6 at the above-described third timing. In FIG. 11, a portion of the irradiation surface 240 which is irradiated with light by the light emitting unit 4 is shown by hatching.

In FIG. 11, the light emitting sections C1, C3, C6, C8, C9, and C11 of the light source 4C are in a turned-on state and the light emitting sections D1, D3, D6, D8, D9, and D11 of the light source 4D are in a turned-off state, and the light emitting sections C2, C4, C5, C7, C10, and C12 of the light source 4C and the light emitting sections D2, D4, D5, D7, D10, and D12 of the light source 4D are in a turned-off state.

As shown in FIG. 11, the light emission drive unit 6 drives the light emitting unit 4 such that one of the light emitting section Ci of the light source 4C and the light emitting section Di of the light source 4D having the same number is in a turned-on state and the other is in a turned-off state at the distance L1 different from the reference distance L2, so that it is possible to irradiate the irradiation sections Pi and Qi and the irradiation sections Pj and Qj adjacent to the irradiation sections Pi and Qi with light beams at different timings.

As a result, the light emission drive unit 6 can more accurately perform the measurement of the distance to the target object existing on the irradiation surface 240 at the distance L1 different from the reference distance L2 as compared with a case where the light emitting section Ci of the light source 4C and the light emitting section Di of the light source 4D having the same number are simultaneously turned on.

Here, in the present exemplary embodiment, determination as to which one of the light emitting section Ci of the light source 4C and the light emitting section Di of the light source 4D is to be put into the turned-on state and which one is to be put into the turned-off state can be made based on the turning-on history of the light source 4C and the light source 4D, as in Exemplary Embodiment 1.

For example, in the example described above, the total turning-on time of the light emitting sections C1, C3, C6, C8, C9, and C11 of the light source 4C and the total turning-on time of the light emitting sections D1, D3, D6, D8, D9, and D11 of the light source 4D are compared, and the light emitting unit 4 need only be driven by the light emission drive unit 6 such that one group of the light emitting sections C1, C3, C6, C8, C9, and C11 and the light emitting sections D1, D3, D6, D8, D9, and D11, which has a shorter total turning-on time, is in a turned-on state and the other group, which has a longer total turning-on time, is in a turned-off state. As a result, in a case where one group of the light emitting sections C1, C3, C6, C8, C9, and C11 of the light source 4C and the light emitting sections D1, D3, D6, D8, D9, and D11 of the light source 4D is in a turned-on state and the other group is in a turned-off state, deviation in the total turning-on times of the light sources 4C and 4D is suppressed as compared with a case where the light emitting sections to be put into the turned-on state and into the turned-off state are fixed.

For the total turning-on time, it is not necessary to strictly compare the sum of times in which the light emitting sections of each light source are turned on in the turning-on history of each light source. For example, the total turning-on time may be compared by excluding a time in which the light emitting section is turned on with an output having less influence on the lifetime of the light source, from the times in which the light emitting sections of each light source are turned on. In addition, in a case where the light emitting sections of each light source emit pulse light at the same time interval, the total number of times of turning on the light emitting sections of each light source may be compared as the turning-on history of the light source.

### Exemplary Embodiment 3

Hereinafter, Exemplary Embodiment 3 of the present invention will be described. In the distance measurement apparatus 1 according to Exemplary Embodiment 3, configurations of the light emitting unit 4 and the light receiving unit 5 included in the optical device 3 are different from the configurations of Exemplary Embodiment 1 and Exemplary Embodiment 2. In Exemplary Embodiment 3, the same configurations as the configurations in Exemplary Embodiment 1 and Exemplary Embodiment 2 are denoted by the same reference numerals, and the detailed description thereof will be omitted here.

### Light Emitting Unit 4

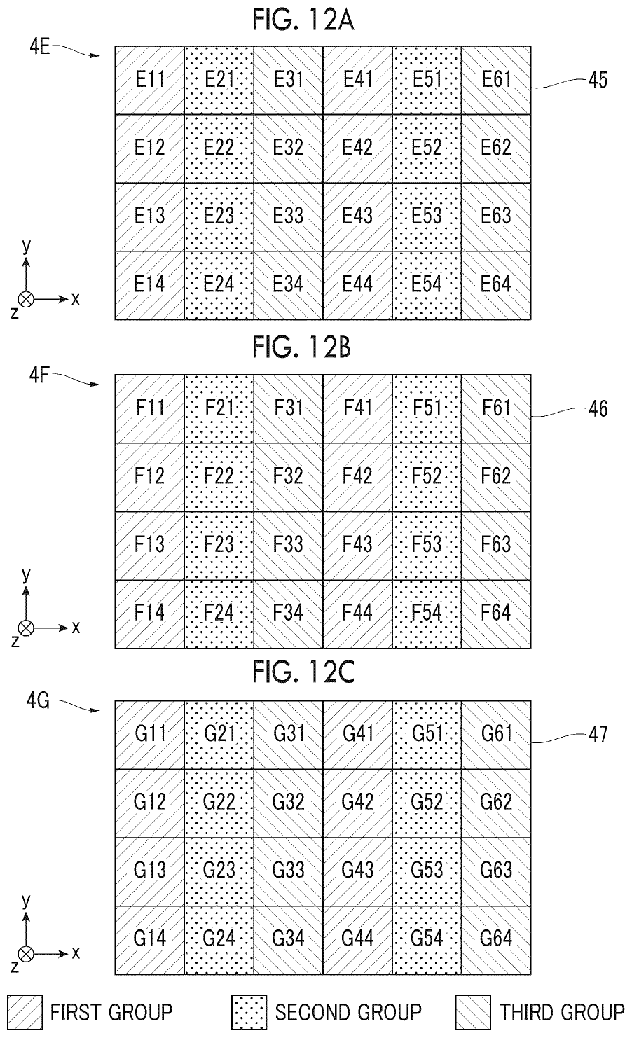

FIGS. 12A to 12C are diagrams describing configurations of light sources 4E, 4F, and 4G included in the light emitting unit 4 according to Exemplary Embodiment 3. In FIGS. 12A to 12C, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. FIGS. 12A to 12C are views showing the light sources 4E, 4F, and 4G of the light emitting unit 4 that emits light, respectively, as viewed from a side opposite to a side on which the light emitting unit 4 emits light.

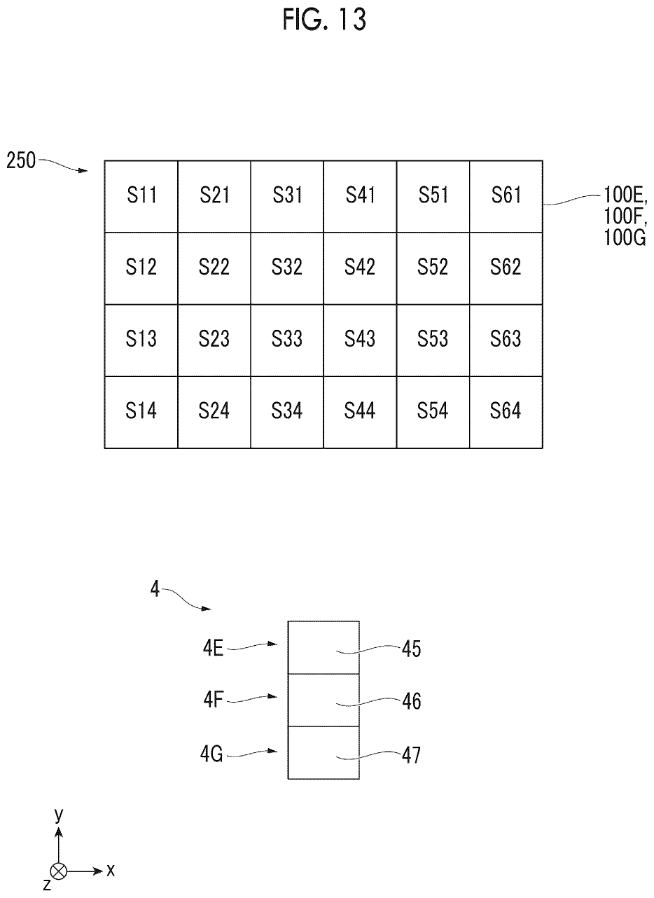

FIG. 13 is a diagram showing the light sources 4E, 4F, and 4G included in the light emitting unit 4 according to Exemplary Embodiment 3 and an irradiation surface 250 that is irradiated with light beams emitted from the light sources 4E, 4F, and 4G. In FIG. 13, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. In FIG. 13, the light emitting unit 4 and the irradiation surface 250 are shown to be shifted in the up-down direction (±y direction), but in reality, the light emitting unit 4 and the irradiation surface 250 are disposed to face each other. In FIG. 13, the light emitting unit 4 is located in the front side direction (−z direction) of the paper plane, and the irradiation surface 250 is located in the back side direction (+z direction) of the paper plane. That is, FIG. 13 is a view of the light emitting unit 4 that emits light as viewed from a side opposite to a side on which the light emitting unit 4 emits light.

Here, a distance in the +z direction from the light sources 4E, 4F, and 4G of the light emitting unit 4 to the irradiation surface 250 is the reference distance L2 (see FIG. 2) described above.

The light emitting unit 4 according to the present exemplary embodiment has the light source 4E that irradiates an irradiation region 100E with light, the light source 4F that irradiates an irradiation region 100F different from the irradiation region 100E with light, and the light source 4G that irradiates an irradiation region 100G different from the irradiation regions 100E and 100F with light. The light emitting unit 4 arranges the irradiation region 100E by the light source 4E, the irradiation region 100F by the light source 4F, and the irradiation region 100G by the light source 4G to be parallel to each other or superimposed on each other and irradiates the irradiation regions 100E, 100F, and 100G with light.

In the light emitting unit 4 according to the present exemplary embodiment, the light sources 4E, 4F, and 4G are disposed in this order in the −y direction.

The light sources 4E, 4F, and 4G according to the present exemplary embodiment have light emitting surfaces 45, 46, and 47 in which a plurality of VCSELs are arranged, respectively. In this example, the light emitting surface 45 of the light source 4E, the light emitting surface 46 of the light source 4F, and the light emitting surface 47 of the light source 4G are arranged in parallel in this order in the −y direction.

The light emitting surface 45 of the light source 4E is divided into 24 light emitting sections Emn (m=natural number of 1 to 6, n=natural number of 1 to 4) in total, for example, six rows in the x direction and four rows in the y direction. m represents a position of the light emitting section Emn in the x direction on the light emitting surface 45, and n represents a position of the light emitting section Emn in the −y direction on the light emitting surface 45. For example, the light emitting section E11 is disposed at a first position in the x direction and a first position in the −y direction from the upper left (the end on the −x direction side and the +y direction side) of the light emitting surface 45, on the light emitting surface 45. The same applies to the light emitting section Fmn of the light source 4F and the light emitting section Gmn of the light source 4G, which will be described below.

The light emitting surface 46 of the light source 4F is divided into 24 light emitting sections Fmn (m=natural number of 1 to 6, n=natural number of 1 to 4) in total, for example, six rows in the x direction and four rows in the y direction.

The light emitting surface 47 of the light source 4G is divided into 24 light emitting sections Gmn (m=natural number of 1 to 6, n=natural number of 1 to 4) in total, for example, six rows in the x direction and four rows in the y direction.

The light emitting sections Emn of the light source 4E, the light emitting sections Fmn of the light source 4F, and the light emitting sections Gmn of the light source 4G are independently driven by the light emission drive unit 6 to emit light. The light emission drive unit 6 drives each light emitting section of the light sources 4E, 4F, and 4G in response to a control signal from the control unit 8. Therefore, the light emitting sections Emn of the light source 4E, the light emitting sections Fmn of the light source 4F, and the light emitting sections Gmn of the light source 4G do not necessarily emit light simultaneously, and a state in which a part of the light emitting sections emits light and the rest of the light emitting sections do not emit light can be taken. In the present exemplary embodiment, a state in which each light emitting section Emn of the light source 4E, each light emitting section Fmn of the light source 4F, and each light emitting section Gmn of the light source 4G are emitting light is referred to as a turned-on state of the light emitting section. In addition, a state in which each light emitting section Emn of the light source 4E, each light emitting section Fmn of the light source 4F, and each light emitting section Gmn of the light source 4G are not emitting light is referred to as a turned-off state of the light emitting section.

The light emission drive unit 6 according to the present exemplary embodiment divides the light emitting sections Emn of the light source 4E, the light emitting sections Fmn of the light source 4F, and the light emitting sections Gmn of the light source 4G into three groups, and drives the light emitting sections to emit light at different timings for each group.

In this example, the light emitting sections Emn of the light source 4E, the light emitting sections Fmn of the light source 4F, and the light emitting sections Gmn of the light source 4G are divided into a first group that irradiates sections S1n and S4n in the irradiation surface 250 with light, a second group that irradiates sections S2n and S5n with light, and a third group that irradiates sections S3n and S6n with light. The light emission drive unit 6 emits light from each light emitting section Emn of the light source 4E, each light emitting section Fmn of the light source 4F, and each light emitting section Gmn of the light source 4G, which belong to each group, in the order of, for example, the first group, the second group, and the third group.

Specifically, the first group includes the light emitting sections E11, E12, E13, E14, E41, E42, E43, and E44 of the light source 4E, the light emitting sections F11, F12, F13, F14, F41, F42, F43, and F44 of the light source 4F, and the light emitting sections G11, G12, G13, G14, G41, G42, G43, and G44 of the light source 4G.

In addition, the second group includes the light emitting sections E21, E22, E23, E24, E51, E52, E53, and E54 of the light source 4E, the light emitting sections F21, F22, F23, F24, F51, F52, F53, and F54 of the light source 4F, and the light emitting sections G21, G22, G23, G24, G51, G52, G53, and G54 of the light source 4G.

In addition, the third group includes the light emitting sections E31, E32, E33, E34, E61, E62, E63, and E64 of the light source 4E, the light emitting sections F31, F32, F33, F34, F61, F62, F63, and F64 of the light source 4F, and the light emitting sections G31, G32, G33, G34, G61, G62, G63, and G64 of the light source 4G.

In addition, the light emitting unit 4 according to the present exemplary embodiment emits light such that the entire irradiation region 100E by the light source 4E, the entire irradiation region 100F by the light source 4F, and the entire irradiation region 100G by the light source 4G are superimposed on each other on the irradiation surface 250 whose distance in the +z direction from the light emitting unit 4 is the reference distance L2.

In this case, in the irradiation surface 250, the light from the light emitting section Emn of the light source 4E, the light from the light emitting section Fmn of the light source 4F, and the light from the light emitting section Gmn of the light source 4F, which have the same numbers m and n, are applied in the same region on the irradiation surface 250. Hereinafter, on the irradiation surface 250, a region in which the light from the light emitting section Emn of the light source 4E, the light from the light emitting section Fmn of the light source 4F, and the light from the light emitting section Gmn of the light source 4F are applied will be denoted by a section Smn. It should be noted that the irradiation surface 250 is divided into 24 sections Smn in total, including six sections in the x direction and four sections in the y direction.

In addition, although not shown, the light emitting unit 4 according to the present exemplary embodiment emits light such that the irradiation region 100E by the light source 4E, the irradiation region 100F by the light source 4F, and the irradiation region 100G by the light source 4G are arranged to be shifted in a direction (for example, the y direction) intersecting the z direction on the irradiation surface whose distance from the light emitting unit 4 is a distance (for example, the distance L1) different from the reference distance L2, as in Exemplary Embodiment 1 and Exemplary Embodiment 2.

In this case, in a case where the light emitting section Emn of the light source 4E, the light emitting section Fmn of the light source 4F, and the light emitting section Gmn of the light source 4G, which are assigned with the same number, are simultaneously turned on, it is difficult to divide the irradiation surface into a plurality of sections and irradiate the sections adjacent to each other with light at different timings, as in the case of Exemplary Embodiment 2.

Therefore, the light emission drive unit 6 according to the present exemplary embodiment puts one of the light emitting section Emn of the light source 4E, the light emitting section Fmn of the light source 4F, and the light emitting section Gmn of the light source 4G, which are assigned with the same number, into a turned-on state, and puts the remaining two into a turned-off state, instead of simultaneously turning on the light emitting section Emn of the light source 4E, the light emitting section Fmn of the light source 4F, and the light emitting section Gmn of the light source 4G, which are assigned with the same number.

More specifically, the light emission drive unit 6 according to the present exemplary embodiment puts one of the light emitting section Emn of the light source 4E, the light emitting section Fmn of the light source 4F, and the light emitting section Gmn of the light source 4G, which belong to the first group, into a turned-on state, and puts the remaining two into a turned-off state, at a timing at which the first group is caused to emit light.

The light emission drive unit 6 puts the light emitting section Emn of the light source 4E, the light emitting section Fmn of the light source 4F, and the light emitting section Gmn of the light source 4G, which belong to the second group and the third group, into a turned-off state, at a timing at which the first group is caused to emit light.

In addition, the light emission drive unit 6 puts one of the light emitting section Emn of the light source 4E, the light emitting section Fmn of the light source 4F, and the light emitting section Gmn of the light source 4G, which belong to the second group, into a turned-on state, and puts the remaining two into a turned-off state, at a timing at which the second group is caused to emit light after the first group is caused to emit light.

The light emission drive unit 6 puts the light emitting section Emn of the light source 4E, the light emitting section Fmn of the light source 4F, and the light emitting section Gmn of the light source 4G, which belong to the first group and the third group, into a turned-off state, at a timing at which the second group is caused to emit light.

Further, the light emission drive unit 6 puts one of the light emitting section Emn of the light source 4E, the light emitting section Fmn of the light source 4F, and the light emitting section Gmn of the light source 4G, which belong to the third group, into a turned-on state, and puts the remaining two into a turned-off state, at a timing at which the third group is caused to emit light after the first group and the second group are caused to emit light.

The light emission drive unit 6 puts the light emitting section Emn of the light source 4E, the light emitting section Fmn of the light source 4F, and the light emitting section Gmn of the light source 4G, which belong to the first group and the second group, into a turned-off state, at a timing at which the third group is caused to emit light.

Here, in the present exemplary embodiment, the light emission drive unit 6 drives the light emitting unit 4 such that the light emitting sections of the light source belonging to each group are in a turned-on state and in a turned-off state, based on the following standard.

That is, the light emission drive unit 6 drives the light emitting unit 4 such that the light emitting sections of the light source in which influence of heat generated by light emission of a previous group on light emission of a next group is small are in a turned-on state and the light emitting sections of the light source in which the influence is large are in a turned-off state.

Specifically, the light emission drive unit 6 controls the light emitting unit 4 such that, for example, at a timing at which the first group is caused to emit light, the light emitting sections E11, E12, E13, E14, E41, E42, E43, and E44 of the light source 4E are in a turned-on state, and the light emitting sections F11, F12, F13, F14, F41, F42, F43, and F44 of the light source 4F and the light emitting sections G11, G12, G13, G14, G41, G42, G43, and G44 of the light source 4G are in a turned-off state in the light sources 4E, 4F, and 4G.

In this case, in the light source 4E, heat is generated due to the light emission of the light emitting sections E11, E12, E13, E14, E41, E42, E43, and E44 in a turned-on state.

Next, the light emission drive unit 6 controls the light emitting unit 4 such that either group of the light emitting sections F21, F22, F23, F24, F51, F52, F53, and F54 of the light source 4F or the light emitting sections G21, G22, G23, G24, G51, G52, G53, and G54 of the light source 4G, in which the influence of heat generated by the light emission of the light emitting sections E11, E12, E13, E14, E41, E42, E43, and E44 of the light source 4E in the first group is small, is in a turned-on state in the light sources 4E, 4F, and 4G, at a timing at which the second group is caused to emit light after the first group is caused to emit light.

In this example, the light emission drive unit 6 controls the light emitting unit 4 such that the light emitting sections F21, F22, F23, F24, F51, F52, F53, and F54 of the light source 4F are in a turned-on state, and the light emitting sections E21, E22, E23, E24, E51, E52, E53, and E54 of the light source 4E and the light emitting sections G21, G22, G23, G24, G51, G52, G53, and G54 of the light source 4G are in a turned-off state, at a timing at which the second group is caused to emit light.

In this case, in the light source 4F, heat is generated due to the light emission of the light emitting sections F21, F22, F23, F24, F51, F52, F53, and F54 in a turned-on state.

Next, the light emission drive unit 6 controls the light emitting unit 4 such that the light emitting sections G31, G32, G33, G34, G61, G62, G63, and G64 of the light source 4G, in which the influence of heat generated by the light emission of the light emitting sections E11, E12, E13, E14, E41, E42, E43, and E44 of the light source 4E in the first group and the light emitting sections F21, F22, F23, F24, F51, F52, F53, and F54 of the light source 4F in the second group is small, are in a turned-on state in the light sources 4E, 4F, and 4G, at a timing at which the third group is caused to emit light after the first group and the second group are caused to emit light.

It should be noted that the light emission drive unit 6 controls the light emitting unit 4 such that the light emitting sections G31, G32, G33, G34, G61, G62, G63, and G64 of the light source 4G are in a turned-on state, and the light emitting sections E31, E32, E33, E34, E61, E62, E63, and E64 of the light source 4E and the light emitting sections F31, F32, F33, F34, F61, F62, F63, and F64 of the light source 4F are in a turned-off state, at a timing at which the third group is caused to emit light.

As described in Exemplary Embodiment 1 as well, in a case where the light emitting sections of the light source are in a turned-on state, heat may be generated due to the light emission of the VCSEL. Then, the temperature of the light emitting section in a turned-on state and the light emitting section adjacent to the light emitting section in a turned-on state increases due to the heat generated by the light emission of the VCSEL. Then, in a case where the temperature of the light emitting section increases, the light emission efficiency of the VCSEL may be affected in a case where the light emitting section is in a turned-on state.

The light emission drive unit 6 according to the present exemplary embodiment puts the light emitting sections of the light source in which an influence of heat generated by light emission of a previous group on light emission of a next group is small into a turned-on state and puts the light emitting sections of the light source in which the influence is large into a turned-off state, thereby suppressing the influence of the heat generated by the light emission on the light emission efficiency, for example, as compared with a case where the light source to be put into the turned-on state and into the turned-off state is fixed.

In Exemplary Embodiment 1 and Exemplary Embodiment 2 described above, a distance at which substantially the entire irradiation regions by the two light sources are superimposed on the irradiation surface is set as the reference distance, and in a case where the target object exists at a distance shorter than the reference distance, one light source is in a turned-on state and the other light source is in a turned-off state. However, the reference distance is not limited to this, and the distance to be used as the reference distance may be set depending on the required accuracy or the like. For example, even in a case where the distance to the target object exists at such a distance that a ratio of a portion in which the irradiation regions by the plurality of light sources are superimposed on each other on the irradiation surface is less than 50%, both light sources may be turned on without turning on one light source and turning off the other light source in a case where the distance measurement accuracy is not so required. In addition, whether to turn on one light source and turn off the other light source, or to turn on the plurality of light sources simultaneously may be switched depending on the accuracy in addition to the required distance.

In addition, in a case where the irradiation surface is divided into a plurality of sections and irradiated with light as in Exemplary Embodiment 2, in the above-described example, the light emitting section Ci of the light source 4C and the light emitting section Di of the light source 4D having the same number are not simultaneously turned on, but the present invention is not limited to this.

In a case where it is possible to divide light and irradiate the plurality of sections of the irradiation surface with the divided light beams, the light emitting section Ci of the light source 4C and the light emitting section Di of the light source 4D having the same number may be turned on simultaneously.

For example, as shown in FIG. 9A, in a case where the light emitting section D1 of the light source 4D is in a turned-on state, a partial region of the irradiation section Q1 that is irradiated with light from the light emitting section D1 is superimposed on the irradiation section P5, but a non-irradiation area that is not irradiated with light from the light emitting section D1 remains in the irradiation section P5. Therefore, even in a case where the light emitting sections C1, C3, C6, C8, C9, and C11 of the light source 4C and the light emitting sections D1, D3, D6, D8, D9, and D11 of the light source 4D are simultaneously turned on, the divisional irradiation between the irradiation area that is irradiated with light beams from these light emitting sections and the non-irradiation area that is not irradiated with the light is barely possible. In this case, the light emitting section Ci of the light source 4C and the light emitting section Di of the light source 4D having the same number may be turned on simultaneously in a light emitting state by using a distance at which the divisional irradiation is barely possible as a reference distance.

On the other hand, the divisional irradiation cannot be performed at a distance at which the region in which the irradiation section Pi and the irradiation section Qi, which have the same number i, are not superimposed on each other is larger compared with the example shown in FIG. 9A and the entire irradiation surface 240 is irradiated with light in a case where the light emitting sections C1, C3, C6, C8, C9, and C11 of the light source 4C and the light emitting sections D1, D3, D6, D8, D9, and D11 of the light source 4D are simultaneously turned on. In this case, one of the light emitting section Ci of the light source 4C and the light emitting section Di of the light source 4D having the same number need only be turned off.

### Exemplary Embodiment 4

Hereinafter, Exemplary Embodiment 4 of the present invention will be described. In the distance measurement apparatus 1 according to Exemplary Embodiment 4, configurations of the light emitting unit 4 and the light receiving unit 5 included in the optical device 3 are different from the configurations of Exemplary Embodiment 1 to Exemplary Embodiment 3. In Exemplary Embodiment 4, the same configurations as the configurations in Exemplary Embodiment 1 to Exemplary Embodiment 3 are denoted by the same reference numerals, and the detailed description thereof will be omitted here.

### Light Emitting Unit 4

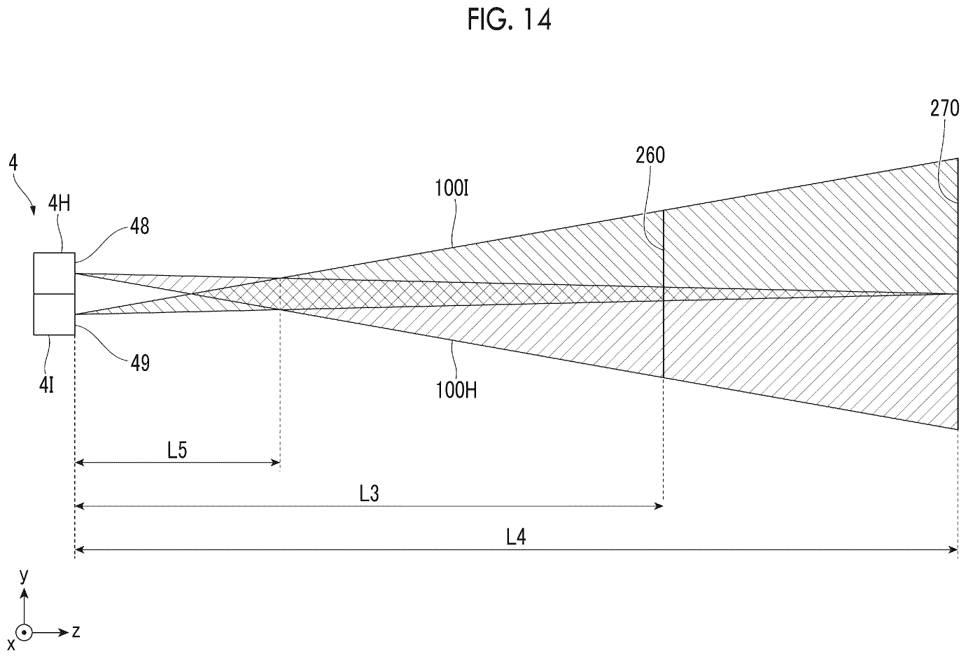

FIG. 14 is a diagram showing light sources 4H and 4I included in the light emitting unit 4 according to Exemplary Embodiment 4 and irradiation regions 100H and 100I which are regions that are irradiated with light beam emitted from the light sources 4H and 4I.

In FIG. 14, a front side of the paper plane is defined as a +x direction, an upper direction of the paper plane is defined as a +y direction, and a right direction of the paper plane is defined as a +z direction. Opposite directions of the directions are defined as −x, −y, and −z directions, respectively.

The light emitting unit 4 has the light source 4H that irradiates the irradiation region 100H with light and the light source 4I that irradiates the irradiation region 100I different from the irradiation region 100H with light. The light emitting unit 4 emits light such that the irradiation region 100H and the irradiation region 100I are parallel to each other at a certain distance (reference distance L4 described below) in a direction (+z direction) in which the light sources 4H and 4I emit light. In this example, the light source 4H is an example of a first light source, the light source 4I is an example of a second light source, the irradiation region 100H is an example of a first irradiation region, and the irradiation region 100I is an example of a second irradiation region.

In the light emitting unit 4 according to the present exemplary embodiment, the light sources 4H and 4I are disposed to be parallel to each other in the y direction. In this example, the light source 4H is disposed on the +y direction side with respect to the light source 4I.

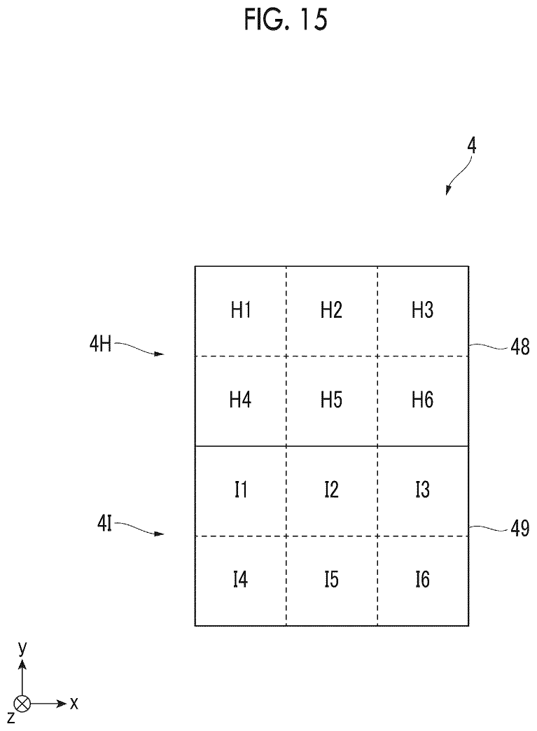

FIG. 15 is a diagram describing configurations of the light sources 4H and 4I included in the light emitting unit 4 according to Exemplary Embodiment 4. In FIG. 15, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively. FIG. 15 is a view of the light sources 4H and 4I of the light emitting unit 4 that emits light as viewed from a side opposite to a side on which the light emitting unit 4 emits light.

The light sources 4H and 4I according to the present exemplary embodiment have light emitting surfaces 48 and 49 in which a plurality of VCSELs are arranged, respectively. In this example, the light emitting surface 48 of the light source 4H is parallel to the light emitting surface 49 of the light source 4I on the +y direction side.

Each of the light emitting surface 48 of the light source 4H and the light emitting surface 49 of the light source 4I is divided into a plurality of light emitting sections including at least one VCSEL. As an example, the light emitting surface 48 of the light source 4H is divided into a total of six light emitting sections H1 to H6 arranged in three rows in the x direction and two rows in the y direction. In this example, the light emitting sections H1 to H6 are located in order from the upper left (the end on the −x direction side and the +y direction side) to the lower right (the end on the +x direction side and the −y direction side) of the light emitting surface 48. Similarly, the light emitting surface 49 of the light source 4I is divided into a total of six light emitting sections I1 to I6 arranged in three rows in the x direction and two rows in the y direction. In this example, the light emitting sections I1 to I6 are located in order from the upper left (the end on the −x direction side and the +y direction side) to the lower right (the end on the +x direction side and the −y direction side) of the light emitting surface 49.

It should be noted that, in the light emitting unit 4 according to the present exemplary embodiment, light emitting sections H4, H5, and H6 in the light emitting surface 48 of the light source 4H are adjacent to light emitting sections I1, I2, and I3 in the light emitting surface 49 of the light source 4I in the y direction.

Each of the light emitting sections H1 to H6 of the light source 4H and each of the light emitting sections I1 to I6 of the light source 4I are independently driven by the light emission drive unit 6 (see FIG. 1) to emit light. The light emission drive unit 6 drives each light emitting section of the light sources 4H and 4I in response to a control signal from the control unit 8 (see FIG. 1). Therefore, the light emitting sections H1 to H6 of the light source 4H and the light emitting sections I1 to I6 of the light source 4I do not necessarily emit light simultaneously, and a state in which a part of the light emitting sections emits light and the rest of the light emitting sections do not emit light can be taken. In the present exemplary embodiment, a state in which each of the light emitting sections H1 to H6 of the light source 4H and each of the light emitting sections I1 to I6 of the light source 4I are emitting light is referred to as a turned-on state of the light emitting section. In addition, a state in which each of the light emitting sections H1 to H6 of the light source 4H and each of the light emitting sections I1 to I6 of the light source 4I are not emitting light is referred to as a turned-off state of the light emitting section.

FIG. 14 shows irradiation surfaces 260 and 270 which are orthogonal to the +z direction and irradiated with the light beams of the irradiation regions 100H and 100I at a certain distance in the direction in which the light sources 4H and 4I emit the light (+z direction). The irradiation surfaces 260 and 270 extend in the x direction and the y direction at a certain distance in the +z direction. In addition, the irradiation surfaces 260 and 270 are arranged in order in the +z direction from the light sources 4H and 4I. Hereinafter, a distance in the +z direction from the light sources 4H and 4I to the irradiation surface 260 will be referred to as a distance L3, and a distance in the +z direction from the light sources 4H and 4I to the irradiation surface 270 will be referred to as a distance L4.

Light beams emitted from the light sources 4H and 4I are refracted by an optical system (not shown) provided in the light sources 4H and 4I and spread and emitted onto a surface perpendicular to the emission direction.

The light emitting unit 4 according to the present exemplary embodiment emits light such that the irradiation region 100H and the irradiation region 100I intersect each other at a certain distance L5 in the +z direction in a case where the light emitting unit 4 is viewed from the +x direction side.

In this case, as shown in FIG. 14, in a region whose distance in the +z direction from the light sources 4H and 4I is less than the distance L5, the irradiation region 100H is located on the +y direction side with respect to the irradiation region 100I. In addition, in a region whose distance in the +z direction from the light sources 4H and 4I exceeds the distance L5, the irradiation region 100H is located on the −y direction side with respect to the irradiation region 100I.

In the distance measurement apparatus 1 according to the present exemplary embodiment, the target object existing in the region whose distance in the +z direction from the light emitting unit 4 exceeds the distance L5 is irradiated with the light beams from the light sources 4H and 4I.

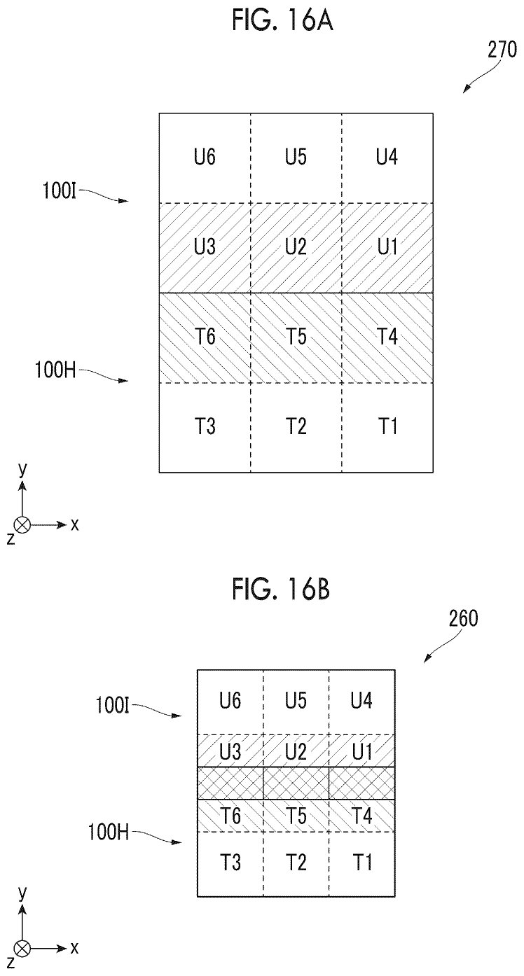

FIGS. 16A and 16B are diagrams describing the irradiation surfaces 260 and 270. FIG. 16A shows the irradiation surface 270 whose distance in the +z direction from the light emitting unit 4 is the distance L4. In addition, FIG. 16B shows the irradiation surface 260 whose distance in the +z direction from the light emitting unit 4 is the distance L3 shorter than the distance L4. In FIGS. 16A and 16B, a right direction of the paper plane is defined as a +x direction, an upper direction of the paper plane is defined as a +y direction, and a back side of the paper plane is defined as a +z direction. Opposite directions of the directions are defined as −x, −y, and −z directions, respectively.

As shown in FIGS. 16A and 16B, on the irradiation surfaces 260 and 270, the irradiation region 100H includes irradiation sections T1 to T6 which are irradiated with the light beams emitted from the light emitting section H1 to H6 of the light source 4H. The irradiation sections T1 to T6 are located in order from the lower right (the end on the +x direction side and the −y direction side) to the upper left (the end on the −x direction side and the +y direction side) of the irradiation region 100H. In the present exemplary embodiment, the arrangement of the irradiation sections T1 to T6 in the irradiation region 100H is reversed with respect to the arrangement of the light emitting sections H1 to H6 on the light emitting surface 48 of the light source 4H in the x direction and the y direction.

Similarly, in the irradiation surfaces 260 and 270, the irradiation region 100I includes irradiation sections U1 to U6 which are irradiated with the light beams emitted from the light emitting sections I1 to I6 of the light source 4I. The irradiation sections U1 to U6 are located in order from the lower right (the end on the +x direction side and the −y direction side) to the upper left (the end on the −x direction side and the +y direction side) of the irradiation region 100I. In the present exemplary embodiment, the arrangement of the irradiation sections U1 to U6 in the irradiation region 100I is reversed with respect to the arrangement of the light emitting sections I1 to I6 on the light emitting surface 49 of the light source 4I in the x direction and the y direction.

As shown in FIG. 16A, in the irradiation surface 270 whose distance in the +z direction from the light emitting unit 4 is the distance L4, the irradiation region 100H by the light source 4H and the irradiation region 100I by the light source 4I are parallel to each other in the y direction. It should be noted that, in the irradiation surface 270, the irradiation region 100H and the irradiation region 100T do not overlap each other.

In the present exemplary embodiment, the distance L4, which is a distance at which the irradiation region 100H and the irradiation region 100I are parallel to each other on the irradiation surface 270, is an example of the reference distance. Hereinafter, the distance L4 may be referred to as a reference distance L4.

In addition, as shown in FIG. 16B, in the irradiation surface 260 whose distance in the +z direction from the light emitting unit 4 is the distance L3 shorter than the reference distance L4, a partial region of the irradiation region 100H by the light source 4H and a partial region of the irradiation region 100I by the light source 4I overlap each other. It should be noted that, in the present exemplary embodiment, in a case where the distance in the +z direction from the light emitting unit 4 is shorter than the reference distance L4, a deviation occurs in a positional relationship between the irradiation region 100H and the irradiation region 100I that are parallel to each other at the reference distance L4, and a partial region of the irradiation region 100H and a partial region of the irradiation region 100I overlap each other.

In the irradiation surface 260, the irradiation sections T4 to T6 of the irradiation region 100H and the irradiation sections U1 to U3 of the irradiation region 100I adjacent to the irradiation sections T4 to T6 in the +y direction overlap each other. More specifically, in the irradiation surface 260, a partial region on the +y direction side of the irradiation sections T4 to T6 of the irradiation region 100H and a partial region on the −y direction side of the irradiation sections U1 to U3 in the irradiation region 100I overlap each other.

### Light Receiving Unit 5

Although not shown, the light receiving unit 5 (see FIG. 1) according to Exemplary Embodiment 4 includes a light receiving surface on which a plurality of light receiving elements are arranged. The light receiving surface is divided into a plurality of light-receiving sections corresponding to the irradiation sections T1 to T6 and the irradiation sections U1 to U6. Specifically, the light receiving surface is divided into a total of 12 light receiving sections arranged in three rows in the x direction and four rows in the y direction.

Each of the light receiving sections receives the light emitted from the light emitting sections H1 to H6 of the light source 4H and the light emitting sections I1 to I6 of the light source 4I and reflected by the target object existing in the irradiation sections T1 to T6 and the irradiation sections U1 to U6. Each light receiving section is independently driven by the light reception drive unit 7 (see FIG. 1) to perform a light receiving operation.

As a result, the light receiving unit 5 according to the present exemplary embodiment can acquire the light reception result for each of the irradiation section T1 to T6 and the irradiation section U1 to U6.

### Drive Control of Light Emitting Unit 4

Subsequently, the drive of the light emitting unit 4 performed by the light emission drive unit 6 based on the control by the control unit 8 will be described.

The light emission drive unit 6 according to the present exemplary embodiment drives the light emitting unit 4 such that, in a case where the light emission drive unit 6 emits light to the irradiation surface 260 whose distance in the +z direction from the light emitting unit 4 is the direction L3 shorter than the reference distance L4, the light emitting sections that irradiate, with light beams, the irradiation sections adjacent to each other in the irradiation region 100H and the irradiation region 100I emit light at different timings.

Specifically, the light emission drive unit 6 causes the light emitting section H4 of the light source 4H, which emits light toward the irradiation section T4, and the light emitting section I1 of the light source 4I, which emits light toward the irradiation section U1 adjacent to the irradiation section T4, to emit light at different timings. In addition, the light emission drive unit 6 causes the light emitting section H5 of the light source 4H, which emits light toward the irradiation section T5, and the light emitting section I2 of the light source 4I, which emits light toward the irradiation section U2 adjacent to the irradiation section T5, to emit light at different timings. Further, the light emission drive unit 6 causes the light emitting section H6 of the light source 4H, which emits light toward the irradiation section T6, and the light emitting section I3 of the light source 4I, which emits light toward the irradiation section U3 adjacent to the irradiation section T6, to emit light at different timings.

Here, in a case where the light emitting section H4 of the light source 4H and the light emitting section I1 of the light source 4I are caused to emit light at the same timing in a case where the irradiation surface 260 is irradiated with light, the irradiation section T4 of the irradiation surface 260 includes a region that is irradiated with the light from the light emitting section H4 and is not irradiated with the light from the light emitting section I1 and a region that is irradiated with the light from the light emitting section H4 and the light from the light emitting section I1 in a superimposed manner. As a result, the intensity of light emitted to the irradiation section T4 is non-uniform.

Similarly, in a case where the light emitting section H4 of the light source 4H and the light emitting section I1 of the light source 4I are caused to emit light at the same timing, the irradiation section U1 of the irradiation surface 260 includes a region that is irradiated with the light from the light emitting section I1 and is not irradiated with the light from the light emitting section H4 and a region that is irradiated with the light from the light emitting section H4 and the light from the light emitting section I1 in a superimposed manner. As a result, the intensity of light emitted to the irradiation section U1 is non-uniform.

In this case, in a case where the target object exists in the irradiation section T4 or the irradiation section U1 on the irradiation surface 260, it may not be possible to accurately perform the measurement of the distance to the target object.

Although detailed description is omitted, in a case where the light emitting sections H5 and H6 of the light source 4H and the light emitting sections I2 and I3 of the light source 4I are caused to emit light at the same timing, the intensity of light to be emitted is also non-uniform in the irradiation sections T5, T6, U2, and U3 of the irradiation surface 260. In this case, it may not be possible to accurately perform the measurement of the distance to the target object.

On the other hand, in the present exemplary embodiment, in a case where the irradiation surface 260 whose distance in the +z direction from the light emitting unit 4 is the distance L3 shorter than the reference distance L4 is irradiated with light, the light emitting units that irradiate, with light beams, the irradiation sections adjacent to each other in the irradiation region 100H and the irradiation region 100I are caused to emit light at different timings, so that the superimposed-manner irradiation with the light from the light emitting section of the light source 4H and the light from the light emitting section of the light source 4I is suppressed in the irradiation section. As a result, the non-uniformity of the intensity of light emitted to the irradiation section is suppressed.

Here, the light emission drive unit 6 may drive the light emitting unit 4 such that, in a case where the light emission drive unit 6 emits light to the irradiation surface 270 whose distance in the +z direction from the light emitting unit 4 is the reference distance L4, the light emitting sections that irradiate, with light beams, the irradiation sections adjacent to each other in the irradiation region 100H and the irradiation region 100I emit light at the same timing.

As described above, in the irradiation surface 270 whose distance in the +z direction from the light emitting unit 4 is the reference distance L4, the irradiation sections adjacent to each other in the irradiation region 100H and the irradiation region 100I do not overlap each other. As a result, in each of the irradiation sections adjacent to each other in the irradiation region 100H and the irradiation region 100I, the intensity of light emitted from the light emitting unit 4 is uniform.

In this case, the influence due to the non-uniformity in the intensity of light emitted to the irradiation section as in the irradiation surface 260 is difficult to occur.

Although the exemplary embodiments of the present invention have been described above, a technical scope of the present invention is not limited to the scope described in the above-mentioned exemplary embodiments. It is apparent from claims that exemplary embodiments in which various modifications or improvements are added to the above-mentioned exemplary embodiments are also included in the technical scope of the present invention.

### SUPPLEMENTARY NOTE

(((1)))

A light emitting device comprising:
a light emitting unit that has a first light source irradiating a first irradiation region with light and a second light source irradiating a second irradiation region with light in a turned-on state and that arranges the first irradiation region and the second irradiation region to be parallel to each other or superimposed on each other at a reference distance and irradiates the first irradiation region and the second irradiation region with light; and
a drive unit that drives the light emitting unit such that one of the first light source and the second light source is in a turned-on state and the other is in a turned-off state in a case where the light emitting unit irradiates a target object at a first distance different from the reference distance with light.
   (((2)))

The light emitting device according to (((1))),
wherein the first light source includes a plurality of light emitting sections that emit light toward each of a plurality of irradiation sections obtained by dividing the first irradiation region,
the second light source includes a plurality of light emitting sections that emit light toward each of a plurality of irradiation sections obtained by dividing the second irradiation region, and
the drive unit drives the light emitting unit such that the light emitting sections, which emit light toward the irradiation sections adjacent to each other, emit light at different timings in each of the first light source and the second light source.
   (((3)))

The light emitting device according to (((2))),
wherein the first light source has a first light emitting section that irradiates a first irradiation section with light and a third light emitting section that irradiates a third irradiation section adjacent to the first irradiation section with light,
the second light source has a second light emitting section that irradiates a second irradiation section with light and a fourth light emitting section that irradiates a fourth irradiation section adjacent to the second irradiation section with light,
at the reference distance, the first irradiation section and the second irradiation section are superimposed on each other, and the third irradiation section and the fourth irradiation section are superimposed on each other, and
the drive unit drives the light emitting unit such that one of the first light source and the second light source is in a turned-on state and the other is in a turned-off state at the first distance at which the first irradiation section and the fourth irradiation section are superimposed on each other.
   (((4)))

The light emitting device according to any one of (((1))) to (((3))), wherein determination as to which one is to be put into the turned-on state and which one is to be put into the turned-off state is made based on a turning-on history of the first light source and the second light source.

(((5)))

The light emitting device according to (((4))),
wherein the drive unit drives the light emitting unit such that one of the first light source and the second light source, which has a shorter total turning-on time, is in a turned-on state and the other, which has a longer total turning-on time, is in a turned-off state in a case where the target object at the first distance is irradiated with light.
   (((6)))

The light emitting device according to (((4))),
wherein each of the first light source and the second light source has a plurality of light emitting sections that emit light toward the first irradiation region and the second irradiation region, and is driven to emit light at a different timing for each group including at least one light emitting section, and
the drive unit drives the light emitting unit such that one of the first light source and the second light source, which has a smaller influence of heat generated by light emission of a previous group on light emission of a next group is in a turned-on state and the other, which has a larger influence, is in a turned-off state in a case where the target object at the first distance is irradiated with light.
   (((7)))

The light emitting device according to any one of (((1))) to (((6))),
wherein the drive unit drives the light emitting unit such that one of the first light source or the second light source is in a turned-on state and the other is in a turned-off state in a case where the target object is detected at the first distance.
   (((8)))

The light emitting device according to any one of (((1))) to (((7))),
wherein the first irradiation region and the second irradiation region are superimposed on each other at the reference distance, and
the first distance is shorter than the reference distance.
   (((9)))

A light emitting device comprising:
a light emitting unit that has a first light source irradiating a first irradiation region with light and a second light source irradiating a second irradiation region with light in a turned-on state and that arranges the first irradiation region and the second irradiation region to be parallel to each other or superimposed on each other at a reference distance and irradiates the first irradiation region and the second irradiation region with light; and
a drive unit that is capable of driving the light emitting unit by switching, via the light emitting unit, a first mode to irradiate a target object at a first distance different from the reference distance and a second mode for irradiating the target object at a distance longer than the first distance with light and that drives the light emitting unit such that one of the first light source and the second light source is in a turned-on state and the other is in a turned-off state in the first mode, and drives the light emitting unit such that both the first light source and the second light source are in a turned-on state in the second mode.
   (((10)))

The light emitting device according to (((9))),
wherein the drive unit drives the light emitting unit in the first mode in a case where arrival of the target object at the first distance is predicted.
   (((11)))

A distance measurement apparatus comprising:
the light emitting device according to any one of (((1))) to (((10)));
a light receiving unit that receives light emitted from the light emitting device and reflected by the target object; and
a calculation unit that calculates a distance to the target object based on a result of the light reception in the light receiving unit.
   (((12)))

The distance measurement apparatus according to (((11))),
wherein the drive unit drives the light emitting unit such that one of the first light source and the second light source is in a turned-on state and the other is in a turned-off state in a case where the target object is detected at the first distance or in a case where arrival of the target object at the first distance is predicted, based on the result of the light reception in the light receiving unit or a result of the calculation in the calculation unit.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting device comprising:
a light emitting unit that has a first light source irradiating a first irradiation region with light and a second light source irradiating a second irradiation region with light in a turned-on state and that arranges the first irradiation region and the second irradiation region to be parallel to each other or superimposed on each other at a reference distance and irradiates the first irradiation region and the second irradiation region with light; and
a drive unit that drives the light emitting unit such that one of the first light source and the second light source is in a turned-on state and the other is in a turned-off state in a case where the light emitting unit irradiates a target object at a first distance different from the reference distance with light.

2. The light emitting device according to claim 1,
wherein the first light source includes a plurality of light emitting sections that emit light toward each of a plurality of irradiation sections obtained by dividing the first irradiation region,
the second light source includes a plurality of light emitting sections that emit light toward each of a plurality of irradiation sections obtained by dividing the second irradiation region, and
the drive unit drives the light emitting unit such that the light emitting sections, which emit light toward the irradiation sections adjacent to each other, emit light at different timings in each of the first light source and the second light source.

3. The light emitting device according to claim 2,
wherein the first light source has a first light emitting section that irradiates a first irradiation section with light and a third light emitting section that irradiates a third irradiation section adjacent to the first irradiation section with light,
the second light source has a second light emitting section that irradiates a second irradiation section with light and a fourth light emitting section that irradiates a fourth irradiation section adjacent to the second irradiation section with light,
at the reference distance, the first irradiation section and the second irradiation section are superimposed on each other, and the third irradiation section and the fourth irradiation section are superimposed on each other, and
the drive unit drives the light emitting unit such that one of the first light source and the second light source is in a turned-on state and the other is in a turned-off state at the first distance at which the first irradiation section and the fourth irradiation section are superimposed on each other.

4. The light emitting device according to claim 1,
wherein determination as to which one is to be put into the turned-on state and which one is to be put into the turned-off state is made based on a turning-on history of the first light source and the second light source.

5. The light emitting device according to claim 4,
wherein the drive unit drives the light emitting unit such that one of the first light source and the second light source, which has a shorter total turning-on time, is in a turned-on state and the other, which has a longer total turning-on time, is in a turned-off state in a case where the target object at the first distance is irradiated with light.

6. The light emitting device according to claim 4,
wherein each of the first light source and the second light source has a plurality of light emitting sections that emit light toward the first irradiation region and the second irradiation region, and is driven to emit light at a different timing for each group including at least one light emitting section, and
the drive unit drives the light emitting unit such that one of the first light source and the second light source, which has a smaller influence of heat generated by light emission of a previous group on light emission of a next group is in a turned-on state and the other, which has a larger influence, is in a turned-off state in a case where the target object at the first distance is irradiated with light.

7. The light emitting device according to claim 1,
wherein the drive unit drives the light emitting unit such that one of the first light source or the second light source is in a turned-on state and the other is in a turned-off state in a case where the target object is detected at the first distance.

8. The light emitting device according to claim 1,
wherein the first irradiation region and the second irradiation region are superimposed on each other at the reference distance, and
the first distance is shorter than the reference distance.

9. A light emitting device comprising:
a light emitting unit that has a first light source irradiating a first irradiation region with light and a second light source irradiating a second irradiation region with light in a turned-on state and that arranges the first irradiation region and the second irradiation region to be parallel to each other or superimposed on each other at a reference distance and irradiates the first irradiation region and the second irradiation region with light; and
a drive unit that is capable of driving the light emitting unit by switching, via the light emitting unit, a first mode to irradiate a target object at a first distance different from the reference distance and a second mode for irradiating the target object at a distance longer than the first distance with light and that drives the light emitting unit such that one of the first light source and the second light source is in a turned-on state and the other is in a turned-off state in the first mode, and drives the light emitting unit such that both the first light source and the second light source are in a turned-on state in the second mode.

10. The light emitting device according to claim 9,
wherein the drive unit drives the light emitting unit in the first mode in a case where arrival of the target object at the first distance is predicted.

11. A distance measurement apparatus comprising:
the light emitting device according to claim 1;
a light receiving unit that receives light emitted from the light emitting device and reflected by the target object; and
a calculation unit that calculates a distance to the target object based on a result of the light reception in the light receiving unit.

12. A distance measurement apparatus comprising:
the light emitting device according to claim 2;
a light receiving unit that receives light emitted from the light emitting device and reflected by the target object; and
a calculation unit that calculates a distance to the target object based on a result of the light reception in the light receiving unit.

13. A distance measurement apparatus comprising:
the light emitting device according to claim 3;
a light receiving unit that receives light emitted from the light emitting device and reflected by the target object; and
a calculation unit that calculates a distance to the target object based on a result of the light reception in the light receiving unit.

14. A distance measurement apparatus comprising:
the light emitting device according to claim 4;
a light receiving unit that receives light emitted from the light emitting device and reflected by the target object; and
a calculation unit that calculates a distance to the target object based on a result of the light reception in the light receiving unit.

15. A distance measurement apparatus comprising:
the light emitting device according to claim 5;
a light receiving unit that receives light emitted from the light emitting device and reflected by the target object; and
a calculation unit that calculates a distance to the target object based on a result of the light reception in the light receiving unit.

16. A distance measurement apparatus comprising:
the light emitting device according to claim 6;
a light receiving unit that receives light emitted from the light emitting device and reflected by the target object; and
a calculation unit that calculates a distance to the target object based on a result of the light reception in the light receiving unit.

17. A distance measurement apparatus comprising:
the light emitting device according to claim 7;
a light receiving unit that receives light emitted from the light emitting device and reflected by the target object; and
a calculation unit that calculates a distance to the target object based on a result of the light reception in the light receiving unit.

18. A distance measurement apparatus comprising:
the light emitting device according to claim 8;
a light receiving unit that receives light emitted from the light emitting device and reflected by the target object; and
a calculation unit that calculates a distance to the target object based on a result of the light reception in the light receiving unit.

19. A distance measurement apparatus comprising:
the light emitting device according to claim 9;
a light receiving unit that receives light emitted from the light emitting device and reflected by the target object; and
a calculation unit that calculates a distance to the target object based on a result of the light reception in the light receiving unit.

20. The distance measurement apparatus according to claim 11,
wherein the drive unit drives the light emitting unit such that one of the first light source and the second light source is in a turned-on state and the other is in a turned-off state in a case where the target object is detected at the first distance or in a case where arrival of the target object at the first distance is predicted, based on the result of the light reception in the light receiving unit or a result of the calculation in the calculation unit.
